(19) United States
(12) Patent Application Publication
(10) Pub. No.: US 2016/0146864 A1
(43) Pub. Date: May 26, 2016

(54) Power System Monitoring and Control Apparatus, and Power System Monitoring and Control Method

(71) Applicant: HITACHI, LTD., Tokyo (JP)

(72) Inventors: Hideyuki KOBAYASHI, Tokyo (JP); Masahiro WATANABE, Tokyo (JP)

(21) Appl. No.: 14/899,455

(22) PCT Filed: Jun. 20, 2013
(86) PCT No.: PCT/JP2013/066980

§ 371 Date: Dec. 17, 2015

(51) Int. Cl. G01R 19/25; G01R 21/133; G01R 31/40

(52) U.S. Cl. CPC G01R 19/2513; G01R 31/40; G01R 21/133

(57) ABSTRACT

To provide a power system monitoring and control apparatus that is capable of acquiring a measurement value at each point in a power system, which, is required for power system monitoring and control, according to the configuration or the physical quantity of the system even under low-speed communication environment. Disclosed is a power system monitoring and control apparatus (1) including: an acquisition apparatus command unit (17) configured to acquire a physical quantity of a power line or a power source by means of a plurality of measurement apparatuses (3), and an acquisition apparatus/interval determination unit (16) configured to select other measurement apparatuses (3) based on the physical quantity acquired by a first measurement apparatus (3), and to determine a time interval, during which the selected measurement apparatuses (3) acquire measurement values, so as to acquire a physical quantity at each point in the vicinity of the first measurement, apparatus among the plurality of measurement apparatuses (3).

### TECHNICAL FIELD

The present invention relates to a power system monitoring and control apparatus, and a power system monitoring and control method which monitor and control a power system.

### BACKGROUND ART

In recent years, small-scale distributed power sources utilizing renewable energies such as sunlight and wind have been popularized. The distributed power sources are disposed in a power system in a distributed manner, and the amount of power generation changes according to external factors such as a change in the weather. The power system, in which the distributed power sources utilizing renewable energies are connected together, undergoes a local voltage increase, a local voltage drop, or the like according to external factors, and the state of the power system, considerably changes every moment. Accordingly, the power quality of the power system decreases, which is a problem. According to a method that is expected as being a mainstream of power system control in the future, the state of the power system is understood by acquiring measurement values from measurement apparatuses installed at points of the power system, and the control amount of the power system is determined in such a way that power quality does not decrease.

The section “demand-area system hybrid test facility” of NPL 1 states that “a remotely controllable system-control device and a remotely controllable system-control system are installed, and a voltage optimization demonstration test is performed as a NEDO's commissioned project”. NPL 1 states that “two SVC s with a capacity of 300 kVA are installed, and are set to be able to operate according to a command value input via communication. Power distribution line sensors are respectively installed at five points on a power distribution line, and are set to be able to measure the voltage of each point or a tidal current. A monitoring and control apparatus is installed at a power transformation station, and is set to be able to communicate with the power distribution line sensors or the SVCs via optical fiber cables”.

A physical quantity at a point, at which a measurement value is not acquired, can be estimated and interpolated from measurement values acquired at other points, NPL 2 states that “an effective power P, a non-effective power Q, a voltage V, and current i, which are not measured, are estimated using the limited measurement data and data of estimation of a change in the power consumption of loads over day”. However, the estimated values have accuracy lower than the measurement values acquired by the measurement apparatuses, which is a problem.

For example, the method disclosed in NPL 3 may be used as power system control means. NPL 3 states that “this study proposes a control method of correcting the set values of LRT and SVR in real time utilizing real-time measurement values at the points in the system”.

### CITATION LIST

### Non-Patent Literature

NPL 1: Hiroyuki Hatta, et al., “Demonstration Evaluation of Voltage Optimization Performed by Remote Control of System-control Device”, power/energy section conference miscellany, Institute of Electrical Engineers of Japan, Sep. 13, 2006, volume 2006, issue 167, p. 23 to p. 24
NPL 2: Masahiro Watanabe, et al., “Investigation of Technique for Estimating State of Power Distribution System Based on Limited Observation Information”, document of power technology study group of Institute of Electrical Engineers of Japan, Institute of Electrical Engineers of Japan, Sep. 28, 2004, volume PE-04, issue 86-100, p. 33 to p. 38
NPL 3: Hideyuki Kobayashi, et al., “Investigation of Adaptive Control of LRT and SVR Utilizing Real-time Measurement Information”, national conference miscellany, Institute of Electrical Engineers of Japan, Mar. 5, 2012, volume 2012, issue 6, p. 293 to p. 294

### SUMMARY OF INVENTION

### Technical Problem

According to the technology disclosed in NPL 1, it is possible to optimize a voltage at each point when electricity is introduced from distributed power sources by remotely controlling the power system control device. However, according to the technology disclosed in NPL 1, measurement data has to be periodically acquired from sensors which are provided at many points. It is not possible to acquire measurement values from the measurement apparatus, which is installed at each point in a power system, at periods required for power system monitoring and control via a low-speed communication network (for example, a power line carrier communication or metal line) of the current power system, which is a problem.

An object of the present invention is to provide a power system monitoring and control apparatus and a power system monitoring and control method which are capable of acquiring a measurement value at each point in a power system, which is required for power system monitoring and control, according to the configuration or the physical quantity of the system even under low-speed communication environment.

### Solution to Problem

In order to solve these problems, according to an aspect of the present invention, there is provided a power system monitoring and control apparatus including: a command unit configured to command a plurality of measurement, apparatuses to acquire a physical quantity of a power line or a power source; and a determination unit configured to select second measurement apparatuses based on the physical quantity acquired by a first measurement apparatus, and to determine a time interval, during which the second measurement apparatuses acquire measurement, values, so as to acquire a physical quantity at each point in the vicinity of the first measurement apparatus among the plurality of measurement apparatuses.

According to another aspect of the present invention, there is provided a power system monitoring and control method that is executed by the power system monitoring and control apparatus. A determination unit executes a step of acquiring a physical quantity by means of a first measurement apparatus among a plurality of measurement apparatuses, a step of selecting second measurement apparatuses based on the physical quantity measured by the first measurement apparatus, and determining a time interval of the acquisition of a measurement value, a step of issuing a command to the second measurement apparatus via the command unit, and a step of acquiring a physical quantity at each point in the vicinity of the first measurement apparatus.

Other means will be described in embodiments of the invention.

### Advantageous Effects of Invention

According to the present invention, the power system monitoring and control apparatus is capable of acquiring a measurement value at each point in a power system, which is required for power system monitoring and control, according to the configuration or the physical quantity of the system even under low-speed communication environment.

### BRIEF DESCRIPTION OF DRAWINGS

FIG. 1 is a block diagram illustrating the logic configuration of a power system monitoring and control apparatus in a first embodiment.

FIG. 2 is a block diagram illustrating the physical configuration of the power system monitoring and control apparatus in the first embodiment.

FIG. 3 is a diagram illustrating an example of the configuration of a power system in the first embodiment.

FIG. 4 is a table illustrating an acquisition apparatus/interval determination rule in the first embodiment.

FIG. 5 is a table illustrating a measurement value history in the first embodiment.

FIG. 6 is a table illustrating an acquisition apparatus/interval determination history in the first embodiment.

FIG. 7 is a flowchart illustrating an acquisition apparatus command process in the first embodiment.

FIG. 8 is a chart illustrating the sequence of the acquisition apparatus command process in the first embodiment.

FIG. 9 is a flowchart illustrating an acquisition apparatus/interval determination process in the first embodiment.

FIG. 10 is a chart illustrating the coincidence of acquisition timings in the first embodiment.

FIG. 11 is a block diagram illustrating the logic configuration of a power system monitoring and control apparatus in a second embodiment.

FIG. 12 is a block diagram illustrating the physical configuration of the power system monitoring and control apparatus in the second embodiment.

FIG. 13 is a flowchart illustrating an acquisition apparatus command process in the second embodiment.

FIG. 14 is a flowchart illustrating a state estimation process in the second embodiment.

FIG. 15 is a flowchart illustrating an acquisition apparatus/interval determination process in the second embodiment.

FIG. 16 is a block diagram illustrating the logic configuration of a power system monitoring and control apparatus in a third embodiment.

FIG. 17 is a flowchart illustrating an acquisition apparatus/interval determination process in the third embodiment.

FIG. 18 is a block diagram illustrating the logic configuration of a power system monitoring and control apparatus in a modification example of the third embodiment.

FIG. 19 is a flowchart illustrating an acquisition apparatus command, process in the modification example of the third embodiment.

FIG. 20 is a flowchart illustrating an acquisition apparatus/interval determination process in the modification example of the third embodiment.

### DESCRIPTION OF EMBODIMENTS

Hereinafter, embodiments of the present invention will be described in detail with reference to the accompanying drawings.

### First Embodiment

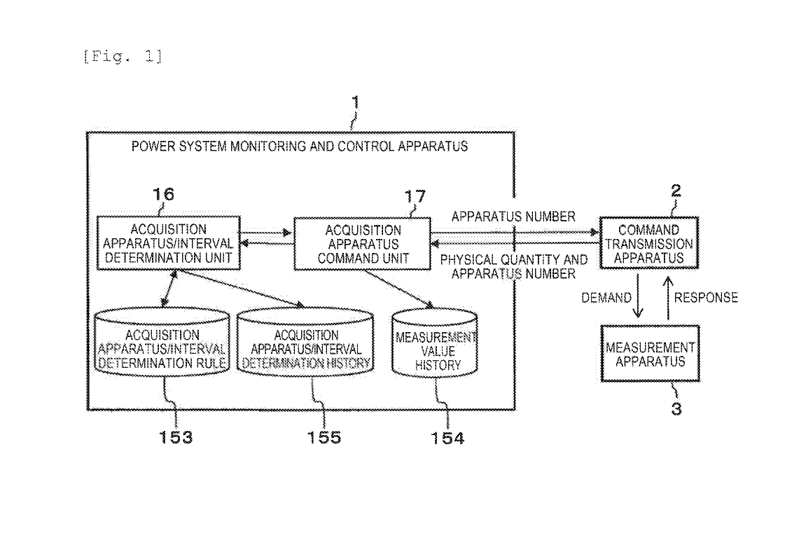

FIG. 1 is a block diagram, illustrating the logic configuration of a power system monitoring and control apparatus 1 in a first embodiment.

As illustrated in FIG. 1, the power system monitoring and control apparatus 1 acquires a measurement value at each point of a power system from a measurement apparatus 3 via a command transmission apparatus 2.

The command transmission apparatus 2 receives a number (hereinafter, which is referred to as an apparatus number), which uniquely specifies the measurement apparatus 3, from the power system monitoring and control apparatus 1, and demands and acquires a physical quantity, which is a measurement value, from the measurement apparatus 3 corresponding to the apparatus number. The physical quantity referred to here contains any one of a voltage, current, an effective power, and a non-effective power. In this manner, the power system monitoring and control apparatus 1 is capable of flexibly monitoring the power system based on any one of the physical quantities. The command transmission apparatus 2 transmits the apparatus number, and the physical quantity of a power source or a power line, which is measured by the measurement apparatus 3 corresponding to the apparatus number, to the power system monitoring and control apparatus 1.

In response to a demand from the command transmission apparatus 2, the measurement apparatus 3 responds to the command transmission apparatus 2 with a physical quantity that is a measurement value at each point of the power system. The measurement apparatus 3 is capable of acquiring the physical quantity of the power line or the power source.

The power system monitoring and control apparatus 1 is configured to include an acquisition apparatus/interval determination unit 16 that is a processing unit; an acquisition apparatus command unit 17 that is a processing unit; an acquisition apparatus/interval determination rule 153 that is data; a measurement value history 154 that is data; and an acquisition apparatus/interval determination history 155 that is data. The power system monitoring and control apparatus 1 transmits an apparatus number to the command transmission apparatus 2, and acquires the apparatus number, and the physical quantity of the power source or the power line which is measured by the measurement apparatus 3 corresponding to the apparatus number.

The acquisition apparatus/interval determination unit 16 is a processing unit that based on the acquisition apparatus/interval determination rule 153, determines measurement conditions corresponding to the physical quantity of the power source or the power line acquired by a first measurement apparatus, and notifies the acquisition apparatus command unit 17 of the measurement conditions. A plurality of the measurement apparatuses 3 include the first measurement apparatus. The acquisition apparatus/interval determination unit 16 determines measurement conditions for acquiring a physical quantity at each point in the vicinity of the first measurement apparatus, and notifies the acquisition apparatus command unit 17 of the measurement conditions. The measurement conditions contain pieces of information regarding the selection of second measurement apparatuses provided at points in the vicinity of the first measurement apparatus, time intervals for acquiring measurement values from the second measurement apparatuses, and the start sequence according to which the second measurement apparatuses acquire measurement values. The second measurement apparatus is also one of the plurality of measurement apparatuses 3. Accordingly, it is possible to limit the second measurement apparatuses which acquire measurement values, or to extend the time interval during which each of the second measurement apparatuses acquires a measurement value, and thus the power system monitoring and control apparatus 1 is capable of monitoring a power system 6 even if a communication path has a low communication speed. The acquisition apparatus/interval determination unit 16 stores the determined measurement conditions in the acquisition apparatus/interval determination history 155.

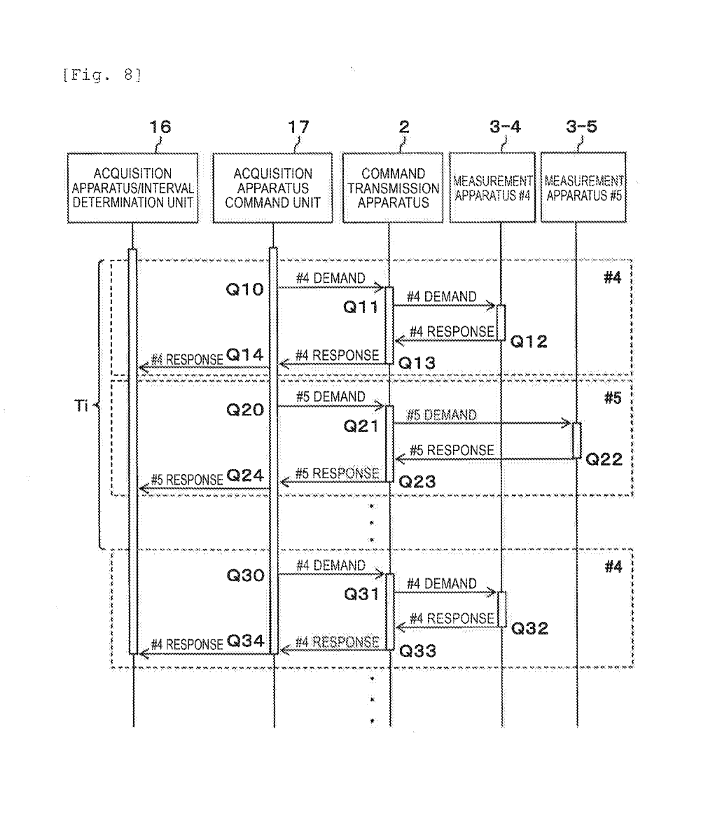

An acquisition apparatus/interval determination process executed by the acquisition apparatus/interval determination unit 16 will be described in detail with reference to FIG. 8.

The acquisition apparatus command unit 17 is a process unit that transmits a command containing an apparatus number to the command transmission apparatus 2 based on the measurement conditions notified from the acquisition apparatus/interval determination unit 16. The acquisition apparatus command unit 17 commands the plurality of measurement apparatuses 3 to acquire physical quantities of the power line or the power source. The acquisition apparatus command unit 17 acquires physical quantities and apparatus numbers via the command transmission apparatus 2. The acquisition apparatus command unit 17 transmits the acquired physical quantities and the acquired apparatus numbers to the acquisition apparatus/interval determination unit 16, and stores in the measurement value history 154.

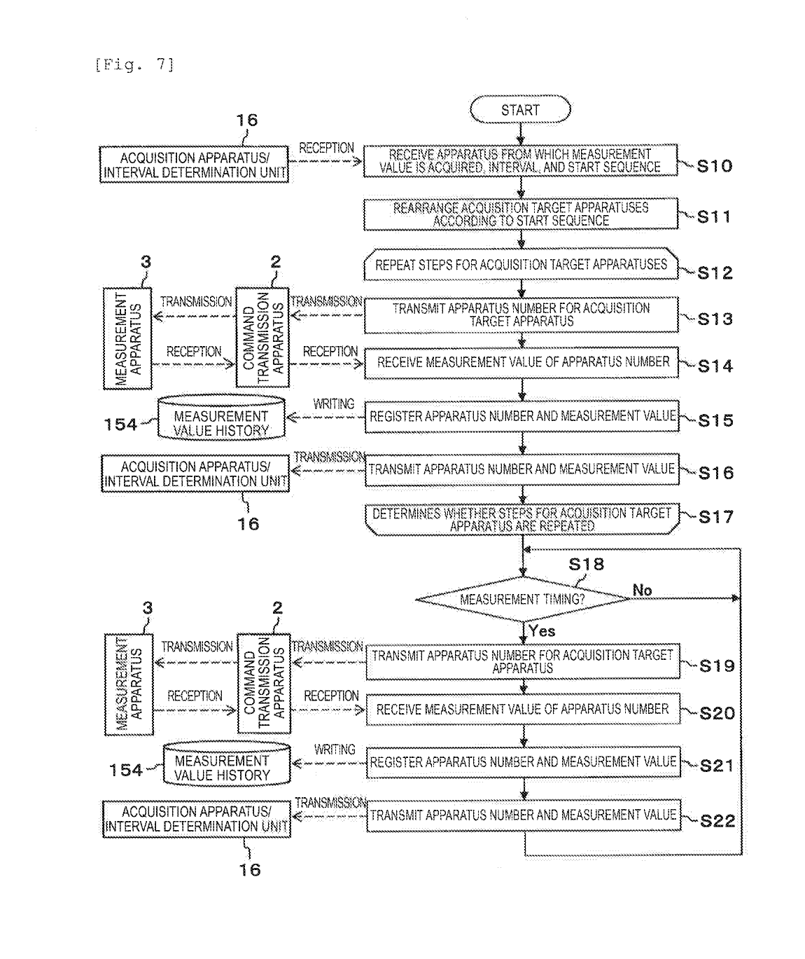

An acquisition apparatus command process executed by the acquisition apparatus command unit 17 will be described in detail with reference to FIG. 7.

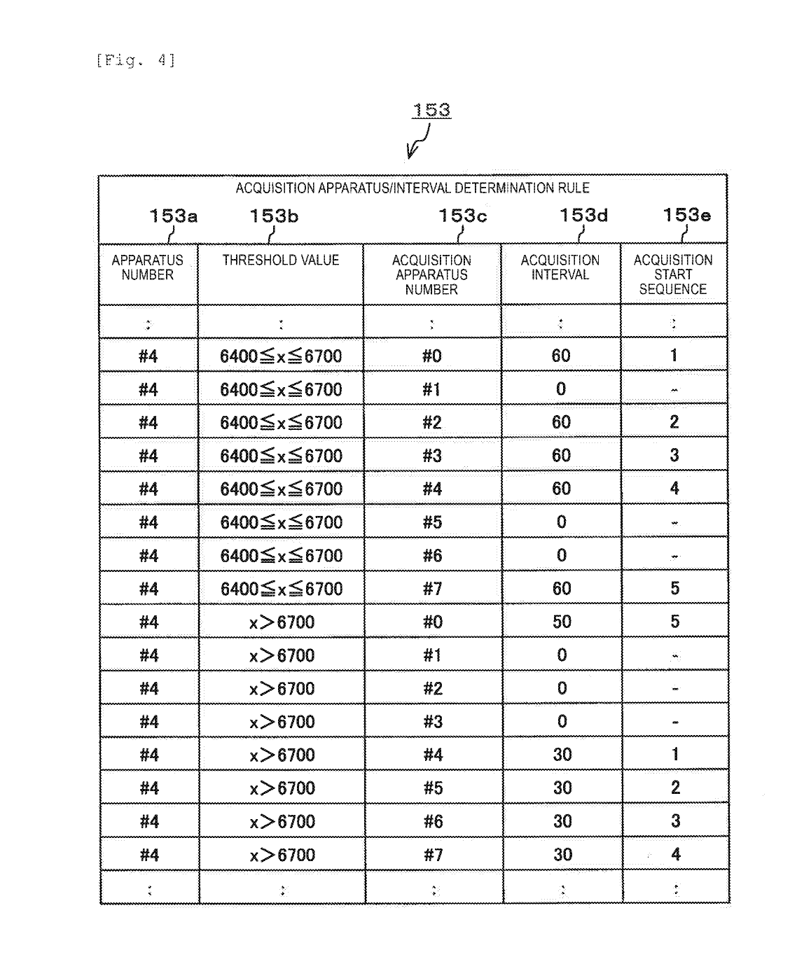

The acquisition apparatus/interval determination rule 153 is a database that defines rules for determining measurement conditions, and will be described in detail with reference to FIG. 4.

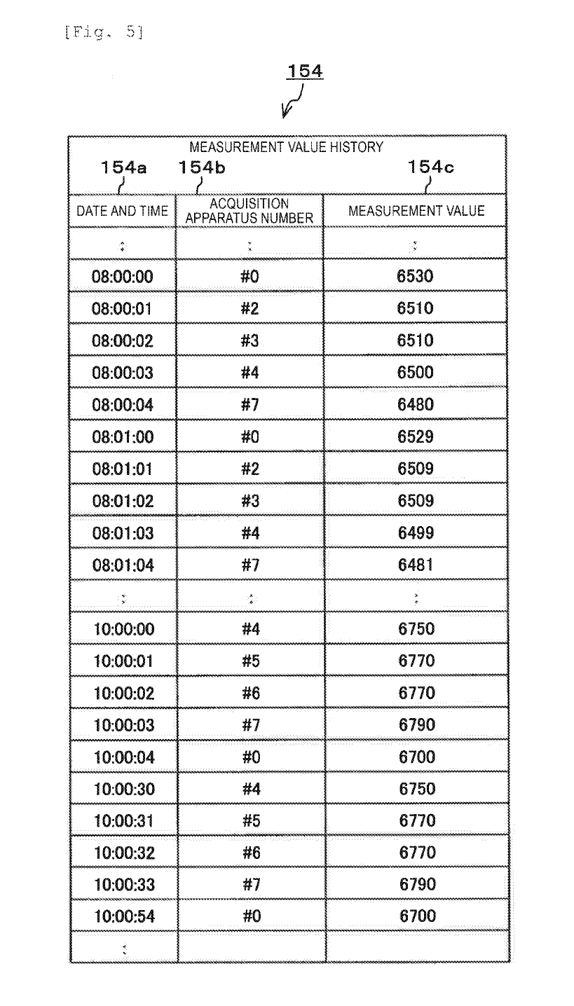

The measurement value history 154 is a database that stores a history of physical quantities (measurement values) of the power source or the power line, and will be described in detail with reference to FIG. 5.

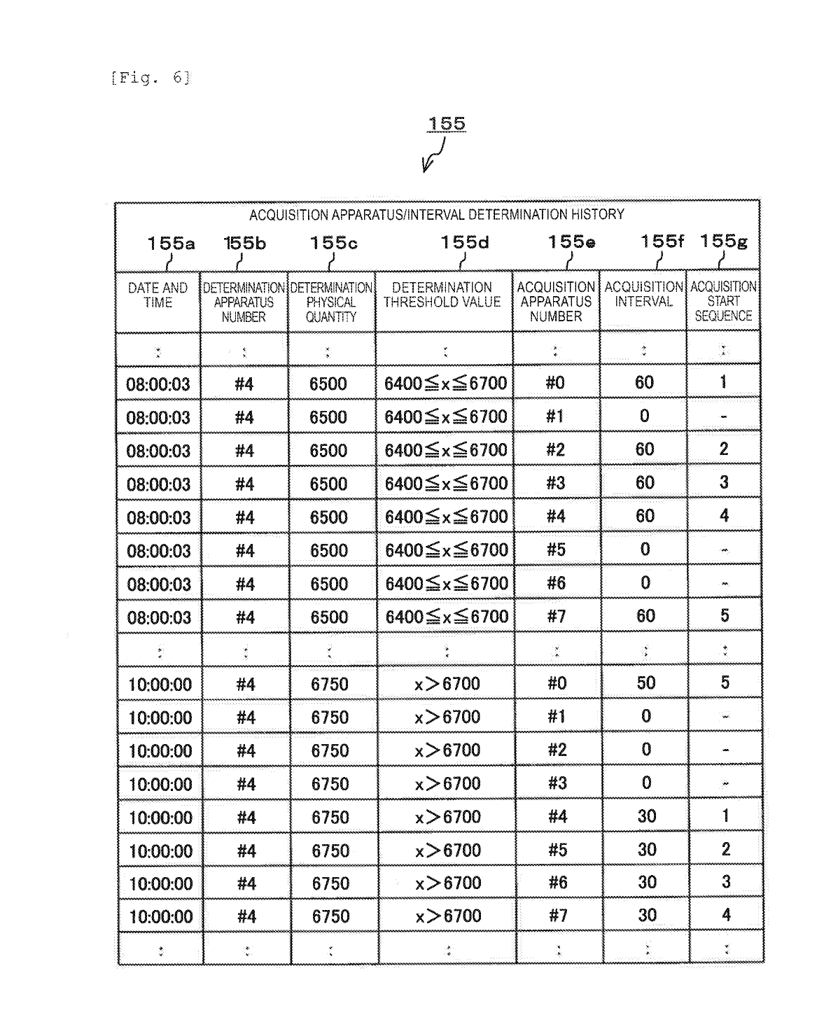

The acquisition apparatus/interval determination history 155 is a database that stores a history of measurement conditions determined by the acquisition apparatus/interval determination unit 16. The configuration of the acquisition apparatus/interval determination history 155 will be described in detail with reference to FIG. 6.

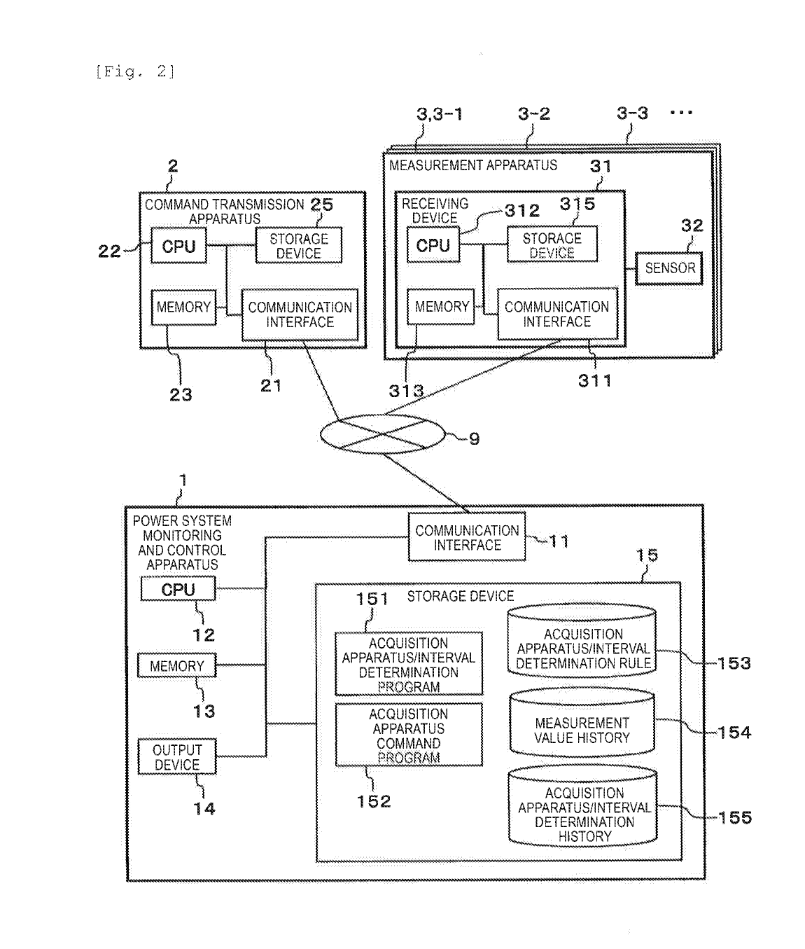

FIG. 2 is a block diagram illustrating the physical configuration of the power system, monitoring and control apparatus 1 in the first embodiment.

The power system monitoring and control apparatus 1 is communicationally connected to the command transmission apparatus 2 and measurement apparatuses 3-1, 3-2, 3-3, . . . via a communication path 9. For example, the communication path 9 is a wired local area network (LAN) or a wireless LAN, and the command transmission apparatus 2, the measurement apparatus 3, the power system monitoring and control apparatus 1, and the like are connected to each other via the communication path 9.

The command transmission apparatus 2 is configured to include a communication interface 21; a central processing unit (CPU) 22; a memory 23; and a storage device 25.

For example, the communication interface 21 is a wire LAN card or a wireless LAN card, and the command transmission apparatus 2 transmits to and receives information from the measurement apparatus 3 or the power system monitoring and control apparatus 1 via the communication path 9.

The CPU 22 is a central processing unit, executes various programs, and integrally controls the command transmission apparatus 2. The CPU 22 is connected to each part of the command transmission apparatus 2 via internal buses.

The memory 23 is a random access memory (RAM) or the like. The memory 23 reads programs or data from the storage device 25 and stores the programs or the data, or temporarily stores information when the CPU 22 executes various programs.

The storage device 25 is a hard disk, a flash memory, or the like, and is a device that stores information such as programs and data.

Each of the measurement apparatuses 3-1, 3-2, 3-3, . . . is configured to include a receiving device 31 and a sensor 32. The measurement, apparatus 3 receives a demand from the command transmission apparatus 2 via the receiving device 31, and measures the physical quantity of the power source or the power line via the sensor 32. Hereinafter, unless specifically differentiated, the measurement apparatuses 3-1, 3-2, 3-3, . . . may be simply referred to as the measurement apparatus 3.

Similar to the command transmission apparatus 2, the receiving device 31 is configured to include a communication interface 311; a CPU 312; a memory 313; and a storage device 315.

The communication interface 311 is similar to the communication interface 21 of the command transmission apparatus 2, and the measurement apparatus 3 transmits to and receives information from the command transmission apparatus 2 or the power system monitoring and control apparatus 1 via the communication path 9.

The CPU 312, the memory 313, and the storage device 315 are respectively similar to the CPU 22, the memory 23, and the storage device 25 of the command transmission apparatus 2.

The sensor 32 is an ammeter, a voltmeter, a wattmeter, or the like, and measures the physical quantity of the power source or the power line such as current, a voltage, a non-effective power, or an effective power.

The power system monitoring and control apparatus 1 is configured to include a communication interface 11; a CPU 12; a memory 13; an output device 14; and a storage device 15.

The output device 14 is a display device, a display lamp, or the like. The output device 14 displays information regarding outputs of various programs of the power system monitoring and control apparatus 1, or data of various databases, or displays information regarding various outputs acquired from the measurement apparatus 3 via the communication path 9. The output device 14 is capable of showing an operator the measurement apparatuses 3 that acquire measurement values, the acquisition intervals, the acquisition start sequence, the reason for the determination thereof by displaying the content of the acquisition apparatus/interval determination history 155. The output, device 14 is capable of showing an operator a past state of the power system 6 by displaying the content of the measurement value history 154.

The communication interface 11 is similar to the communication interface 21 of the command transmission apparatus 2, and the power system monitoring and control apparatus 1 transmits to and receives information from the command transmission apparatus 2 or the measurement apparatus 3 via the communication path 9.

The CPU 12 and the memory 13 are respectively similar to the CPU 22 and the memory 23 of the command transmission apparatus 2.

The storage device 15 is similar to the storage device 25 of the command transmission apparatus 2, and stores an acquisition apparatus/interval determination program 151 and an acquisition apparatus command program 152 as programs. The storage device 15 further stores the acquisition apparatus/interval determination rule 153, the measurement value history 154, and the acquisition apparatus/interval determination history 155 as data.

The acquisition apparatus/interval determination program 151 is read onto the memory 13, and is executed by the CPU 12 such that the acquisition apparatus/interval determination unit 16 (refer to FIG. 1) is realized.

Similarly, the acquisition apparatus command program. 152 is read onto the memory 13, and is executed by the CPU 12 such that the acquisition apparatus command unit 17 (refer to FIG. 1) is realized.

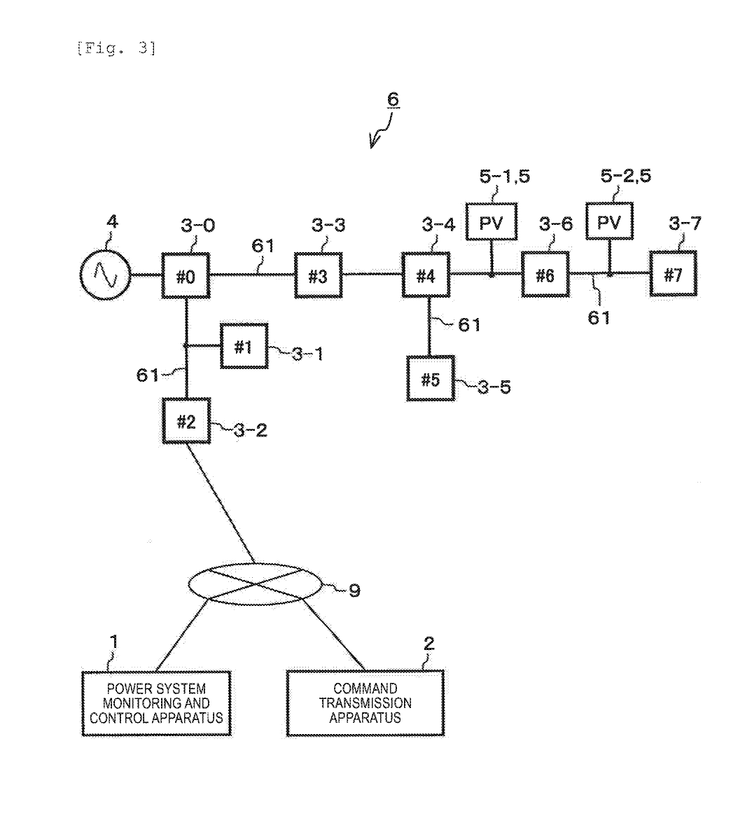

FIG. 3 is a diagram illustrating an example of the configuration of the power system 6 in the first embodiment.

As illustrated in FIG. 3, the power system 6 is configured to include a power distribution and transformation station 4; measurement apparatuses 3-0 to 3-7; photovoltaic apparatuses (PV: photovoltaics) 5-1 and 5-2; a load (not illustrated); and a power line 61 that connects together the aforementioned configuration elements. The power system 6 supplies electricity to the load (not illustrated).

The power distribution and transformation station 4 transforms the voltage of electricity from, an upper system (not illustrated) into the voltage of the power system 6, and then supplies electricity with the transformed voltage.

The measurement apparatuses 3-0 to 3-7 measure physical quantities at points in the power system 6, respectively. An apparatus number #0 is assigned to the measurement apparatus 3-0. Similarly, apparatus numbers #1 to #7 are respectively assigned to the measurement apparatuses 3-1 to 3-7.

The photovoltaic apparatuses 5-1 and 5-2 generate electricity by receiving sunlight, and supply the electricity in conjunction with the power system 6. Hereinafter, unless specifically differentiated, the photovoltaic apparatuses 5-1 and 5-2 may be simply referred to as a photovoltaic apparatus 5.

The command transmission apparatus 2 and the power system monitoring and control apparatus 1 are capable of communicating with the measurement apparatuses 3-0 to 3-7 via the communication path 9. In FIG. 3, the measurement apparatus 3-2 connected to the command transmission apparatus 2 via the communication path 9 is illustrated as a representative of the measurement apparatus 3.

FIG. 4 is a table illustrating the acquisition apparatus/interval determination rule 153 in the first embodiment.

The acquisition apparatus/interval determination rule 153 is a database that defines the measurement apparatuses 3 which acquire measurement values, the acquisition intervals, and the acquisition start sequence. The acquisition apparatus/interval determination unit 16 acquires measurement, values based on the acquisition apparatus/interval determination rule 153. As such, the determination rule is configured as a database, and thus can be flexibly revised compared to when the determination rule is assembled into a program.

As items, the acquisition apparatus/interval determination rule 153 contains an apparatus number column 153a, a threshold value column 153b, an acquisition apparatus number column 153c, an acquisition interval column 153d, and an acquisition start sequence column 153e.

The apparatus number column 153a stores a number that uniquely specifies the first measurement apparatus so as to determine a threshold value for a physical quantity. In the first embodiment, the measurement apparatus 3-4 with apparatus number #4 is selected as the first measurement apparatus. The first measurement apparatus is provided at the power source that supplies electricity to the power system 6, a branch point of the power line 61 of the power system 6, or the like, and thus the first measurement apparatus is capable of suitably understanding the state of the power system 6.

The threshold value column 153b stores threshold, value conditions for physical quantities acquired by the first, measurement apparatus.

The acquisition apparatus number column 153c stores numbers uniquely specifying the respective second measurement apparatuses which acquire new measurement values. The second measurement apparatus is the measurement apparatus 3 that acquires a new measurement value when a physical quantity acquired by the first measurement apparatus satisfies the conditions in the threshold value column 153b.

The acquisition interval column 153d stores time intervals during which the second measurement apparatuses acquire measurement values.

The acquisition start sequence column 153e stores the sequence according to which the second measurement, apparatuses acquire measurement values. When any one of the second measurement apparatuses is set to have a high acquisition sequence in the acquisition start sequence column 153e, the acquisition apparatus command unit 17 (refer to FIG. 1) is capable of acquiring a measurement value from the second measurement, apparatus at a more accurate timing.

An example of the rule of determining the measurement apparatus 3 will be described. When a physical quantity acquired by the first measurement apparatus, which periodically acquires a measurement value, is within a proper range, measurement values are acquired from the second measurement apparatuses widely distributed over the entirety of the power system 6 so as to widely monitor the entire power system 6. At this time, physical quantities at points at which measurement values are not acquired are estimated and interpolated based on measurement values acquired at the other points. The estimated value is less accurate than the measurement value acquired by the measurement apparatus 3. For example, the method disclosed in NPL 2 may be used as an estimation method.

Records in second to ninth rows in FIG. 4 represent that conditions of measurement values (voltages) of the measurement apparatus 3-4 with apparatus number #4 are within a proper range (greater than or equal to 6400 and less than or equal to 6700).

According to the record in the second row, it is determined that measurement values are acquired from the measurement apparatus 3 with apparatus number #0 at time intervals of 60 seconds. According to the records in the fourth to sixth rows, it is determined that measurement values are acquired from the measurement apparatuses 3 with apparatus numbers #2 to #4 at time intervals of 60 seconds. According to the record in the ninth row, it is determined that measurement values are acquired from the measurement apparatus 3 with apparatus number #7 at time intervals of 60 seconds.

According to the record in the third row, and the records in the seventh and eighth rows, it is determined that measurement values are not acquired from the measurement apparatuses 3 with apparatus numbers #1, #5, and #6. An acquisition interval of “0” and an acquisition start sequence of imply that measurement values are not acquired from the second measurement apparatus.

When the physical quantity of the first measurement apparatus 3-4, which periodically acquires a measurement value, is out of a proper range, it is necessary to monitor the vicinity of the first measurement apparatus with high accuracy. Instead of relying on low-accuracy estimation or interpolation, measurement values are more frequently acquired from a group of the second measurement apparatuses which measure physical quantities at points in the vicinity of the first measurement apparatus. In contrast, measurement values are less frequently acquired from the measurement apparatuses 3 which are present at the other points.

For example, records in the tenth to seventeenth rows in FIG. 4 represent that conditions of measurement values (voltages) of the measurement apparatus 3-4 with apparatus number #4 is out of the appropriate range (greater than 6700). According to the records in the tenth to seventeenth rows, it is determined that measurement values are more frequently acquired from a group of the second measurement apparatuses 3 in the vicinity of the first measurement apparatus 3-4, and to that extent, measurement, values are less frequently acquired from the measurement apparatuses 3 which are present at the other points.

FIG. 5 is a table illustrating the measurement value history 154 in the first, embodiment.

As illustrated in FIG. 5, the measurement value history 154 is a database that manages a history of measurement values acquired by the acquisition apparatus command unit 17.

As items, the measurement value history 154 contains a date and time column 154a, an acquisition apparatus number column 154b, and a measurement value column 154c.

The date and time column 154a stores dates and times on which the acquisition apparatus command unit 17 acquires measurement values.

The acquisition apparatus number column 154b stores the apparatus numbers of the measurement apparatuses 3 from which the acquisition apparatus command unit 17 acquires measurement values.

The measurement value column 154c stores the measurement values (physical quantities) acquired by the acquisition apparatus command unit 17.

For example, a second row represents that a measurement value 6530 is acquired from the measurement apparatus 3-0 with apparatus number #0 at 8 o'clock, 0 minutes, 0 seconds. A third row represents that a measurement value 6510 is acquired from the measurement apparatus 3-2 with apparatus number #2 at 8 o'clock, 0 minutes, 1 second which is one second thereafter. A fourth row represents that the measurement value 6510 is acquired from the measurement apparatus 3-3 with apparatus number #3 at 8 o'clock, 0 minutes, 2 seconds which is one second thereafter. A fifth row represents that a measurement value 6500 is acquired from the measurement apparatus 3-4 with apparatus number #4 at 8 o'clock, 0 minutes, 3 seconds which is one second thereafter. A sixth row represents that a measurement value 6480 is acquired from the measurement apparatus 3-7 with apparatus number #7 at 8 o'clock, 0 minutes, 4 seconds which is one second thereafter. That is, the second to sixth rows represent that measurement values are acquired from the measurement apparatuses 3 at intervals of one second according to the sequence in the acquisition start sequence column 153e.

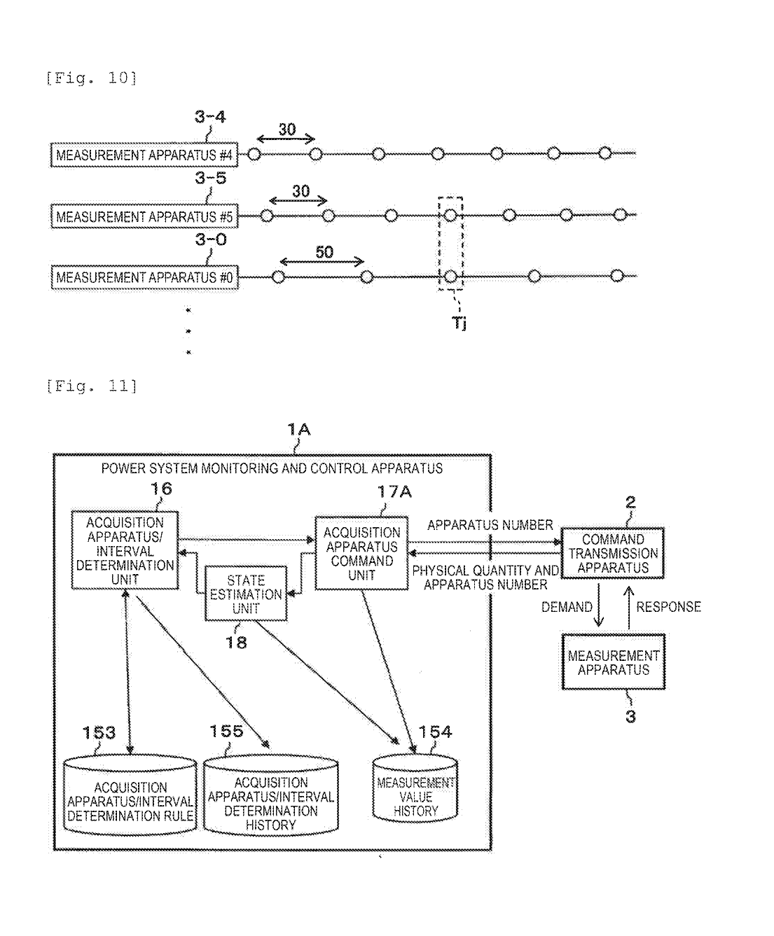

As such, the acquisition apparatus command unit 17 acquires measurement values from the measurement apparatuses 3 at predetermined time intervals according to the sequence in the acquisition start sequence column 153e. Accordingly, the power system monitoring and control apparatus 1 acquires the measurement values from the second measurement apparatuses at the predetermined time intervals, and thus the power system monitoring and control apparatus 1 is capable of monitoring the power system 6 even if the communication path 9 has a low communication speed. The power system monitoring and control apparatus 1 is capable of avoiding the coincidence of acquisition timings (to be described later) as illustrated in FIG. 10 by studying values in the acquisition interval column 153d. As illustrated in FIG. 4, the study of the values in the acquisition interval column 153d implies that all the records in the acquisition interval column 153d are set to the same value of 60 seconds greater than a value (five seconds) that is obtained by multiplying the number (five) of selected second measurement apparatuses by a predetermined amount of time (one second). However, the study of the values in the acquisition interval column 153d is not limited to that method, and may be performed by other methods insofar as the coincidence of acquisition timings can be avoided. For example, the least common multiple (10 seconds) of the values in the acquisition interval column 153d for the selected second measurement, apparatuses may be set to be greater than the value (five seconds) that is obtained by multiplying the number of selected second measurement apparatuses by the predetermined amount of time.

FIG. 6 is a table illustrating the acquisition apparatus/interval determination history 155 in the first, embodiment.

As illustrated in FIG. 6, the acquisition apparatus/interval determination history 155 is a database that manages a history of determinations performed by the acquisition apparatus/interval determination unit 16.

As items, the acquisition apparatus/interval determination history 155 contains a date and time column 155a, a determination apparatus number column 155b, a determination physical quantity column 155c, a determination threshold value column 155d, an acquisition apparatus number column 155e, an acquisition interval column 155f, and an acquisition start sequence column 155g.

The date and time column 155a stores dates and times on which the acquisition apparatus/interval determination unit 16 determines acquisition apparatuses, acquisition intervals, and the like.

The determination apparatus number column 155b stores a number which uniquely specifies the first measurement apparatus.

The determination physical quantity column 155c stores physical quantities acquired by the first measurement apparatus. The acquisition apparatus/interval, determination unit 16 determines the acquisition apparatuses, the acquisition intervals, and the like based on the physical quantities acquired by the first measurement apparatus.

The determination threshold value column 155d stores threshold value conditions. The acquisition apparatus/interval determination unit 16 determines the physical quantities acquired by the first measurement apparatus, based on the threshold value conditions.

The acquisition apparatus number column 155e stores numbers which uniquely specify the second measurement apparatuses, respectively. The second measurement apparatuses are determined, are registered in the acquisition apparatus number column 155e, and are transmitted to the acquisition apparatus command unit 17 by the acquisition apparatus/interval determination unit 16. The acquisition apparatus command unit 17 acquires new measurement values from the second measurement apparatuses.

The acquisition interval column 155f stores acquisition intervals for the second measurement apparatuses. The acquisition intervals for the second, measurement apparatuses are determined, are registered in the acquisition interval column 155f, and are transmitted to the acquisition apparatus command unit 17 by the acquisition apparatus/interval determination unit 16. The acquisition apparatus command unit 17 acquires new measurement values from the second measurement apparatuses at the acquisition intervals stored in the acquisition interval column 155f.

The acquisition start sequence column 155g stores the sequence according to which the second, measurement apparatuses acquire measurement values. The sequence for the acquisition of measurement values between the second measurement apparatuses are determined, are registered in the acquisition start sequence column 155g, and are transmitted to the acquisition apparatus command unit 17 by the acquisition apparatus/interval determination unit 16. The acquisition apparatus command unit 17 acquires new measurement, values from the second measurement apparatuses according to the acquisition sequences stored in the acquisition start sequence column 155g. As such, the acquisition apparatus/interval determination history 155 contains the acquisition start sequence column 155g, and thus it is possible to later confirm the sequence according to which the second measurement apparatuses acquire measurement values.

FIG. 7 is a flowchart illustrating the acquisition apparatus command process in the first embodiment.

The acquisition apparatus command program 152 is executed by the CPU 12 such that the acquisition apparatus command unit 17 is realized, and starts the process.

In step S10, the acquisition apparatus command unit 17 receives (acquires) pieces of information regarding a combination of acquisition target apparatuses from, the acquisition apparatus/interval determination unit 16, with each piece of information containing an apparatus number for an apparatus from, which a measurement value is acquired, the acquisition interval, and the acquisition start sequence. The acquisition apparatus command process starts upon the receipt. The acquisition target apparatus referred to here is the second measurement apparatus.

In step S11, the acquisition apparatus command unit 17 rearranges the received combination of acquisition target apparatuses according to the acquisition start sequence.

The acquisition apparatus command unit 17 repeats steps S12 to S17 for the acquisition target apparatuses. The acquisition apparatus command unit 17 acquires an initial measurement value from each of the acquisition target apparatuses according to the acquisition start sequence by performing these steps.

In step S13, the acquisition apparatus command unit 17 transmits an apparatus number for the acquisition target apparatus to the command transmission apparatus 2. The command transmission apparatus 2 transmits a demand for a measurement value to the measurement apparatus 3 corresponding to the received apparatus number, and receives the apparatus number and the measurement value from the measurement apparatus 3.

In step S14, the acquisition apparatus command unit 17 receives a combination of the apparatus number and the measurement value from the command transmission apparatus 2. Accordingly, the acquisition apparatus command unit 17 is capable of directly acquiring a physical quantity at each point in the vicinity of the first measurement apparatus by means of the acquisition target apparatus, and thus the acquisition apparatus command unit 17 is capable of accurately measuring the physical quantity.

In step S15, the acquisition apparatus command unit 17 writes and registers the combination of the apparatus number and the measurement value in the measurement value history 154. Accordingly, an operator of the power system 6 can analyze a malfunction or the like of the power system 6 later based on the history for each point of the power system 6.

In step S16, the acquisition apparatus command unit 17 transmits the combination of the apparatus number and the measurement value to the acquisition apparatus/interval determination unit 16.

In step S17, the acquisition apparatus command unit 17 determines whether the steps for the acquisition target apparatus are repeated. When conditions for the determination are not established, the acquisition apparatus command unit 17 returns to step S12.

In step S18, based on a previous measurement value acquisition timing and the acquisition interval of each of the acquisition target apparatuses, the acquisition apparatus command unit 17 determines whether a current time is a measurement timing of any one of the acquisition target apparatuses. When the determination conditions are not established, the acquisition apparatus command unit 17 repeats step S18, and when the determination conditions are established, the acquisition apparatus command unit 17 performs step S19. In step S18, when acquisition timings of a plurality of the acquisition target apparatuses coincide with each other, the acquisition apparatus command unit 17 performs steps for the acquisition target apparatus with an early acquisition start sequence prior to other acquisition target apparatuses. Steps S19 to S22 to be illustrated hereinafter are the same as steps S13 to S16.

In step S19, the acquisition apparatus command unit 17 transmits an apparatus number for the acquisition target apparatus to the command transmission apparatus 2. The command transmission apparatus 2 transmits a demand, for a measurement value to the measurement apparatus 3 corresponding to the received apparatus number, and receives the apparatus number and the measurement value from, the measurement apparatus 3.

In step S20, the acquisition apparatus command unit 17 receives a combination of the apparatus number and the measurement value from the command transmission apparatus 2.

In step S21, the acquisition apparatus command unit 17 writes and registers the combination of the apparatus number and the measurement, value in the measurement value history 154.

In step S22, the acquisition apparatus command unit 17 transmits the combination of the apparatus number and the measurement value to the acquisition apparatus/interval determination unit 16, and returns to step S18.

FIG. 8 is a chart illustrating the sequence of the acquisition apparatus command process in the first embodiment.

#4 surrounded by a dotted line illustrates a sequence for the measurement apparatus 3-4 with apparatus number #4, #5 surrounded by a dotted line illustrates a sequence for the measurement apparatus 3-5 with apparatus number #5. A time interval Ti represents a time interval during which the measurement apparatus 3-4 with apparatus number #4 acquires a physical quantity.

In sequence Q10, the acquisition apparatus command unit 17 transmits a demand for a physical quantity of the measurement apparatus 3-4 with apparatus number #4 to the command transmission apparatus 2. The measurement apparatus 3-4 referred to here is the first measurement apparatus.

In sequence Q11, the command transmission apparatus 2 transmits a demand for a physical quantity to the measurement apparatus 3-4 with apparatus number #4.

In sequence Q12, the measurement apparatus 3-4 with apparatus number #4 responds to the command transmission apparatus 2 with a physical quantity measured by the sensor 32.

In sequence Q13, the command transmission apparatus 2 responds to the acquisition apparatus command unit 17 with the physical quantity measured by the measurement apparatus 3-4 with apparatus number #4.

In sequence Q14, the acquisition apparatus command unit 17 responds to the acquisition apparatus/interval determination unit 16 with the physical quantity measured by the measurement apparatus 3-4 with apparatus number #4. As a result, the acquisition apparatus/interval determination unit 16 is capable of acquiring the physical quantity of the power line or the power source measured by the first measurement apparatus.

In sequence Q20, the acquisition apparatus command unit 17 transmits a demand for a physical quantity of the measurement apparatus 3-5 with apparatus number #5 to the command transmission apparatus 2. The measurement apparatus 3-5 referred to here is the second measurement apparatus.

In sequence Q21, the command transmission apparatus 2 transmits a demand for a physical quantity to the measurement apparatus 3-5 with apparatus number #5.

In sequence Q22, the measurement apparatus 3-5 with apparatus number #5 responds to the command transmission apparatus 2 with a measured physical quantity.

In sequence Q23, the command transmission apparatus 2 responds to the acquisition apparatus command unit 17 with the physical quantity measured by the measurement apparatus 3-5 with apparatus number #5.

In sequence Q24, the acquisition apparatus command unit 17 responds to the acquisition apparatus/interval determination unit 16 with the physical quantity measured by the measurement apparatus 3-5 with apparatus number #5. As a result, the acquisition apparatus/interval determination unit 16 is capable of acquiring the physical quantity of the power line or the power source measured by the second measurement apparatus.

Sequences Q30 to Q34 are the same as sequences Q10 to Q14.

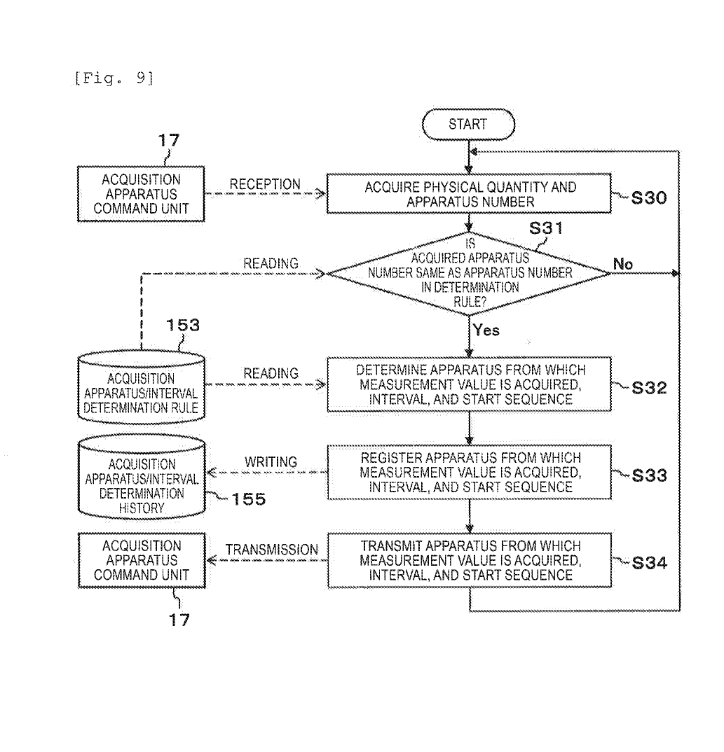

FIG. 9 is a flowchart illustrating the acquisition apparatus/interval determination process in the first embodiment.

The acquisition apparatus/interval determination program 15i is executed by the CPU 12 such that the acquisition apparatus/interval determination unit 16 is realized, and starts the process. When the acquisition apparatus/interval determination unit 16 receives the physical quantity of a power line 61 or the physical quantity of the power source, the acquisition apparatus/interval determination unit 16 determines and transmits the measurement apparatus 3 from which a measurement value is acquired, the acquisition interval, and the acquisition start sequence to the acquisition apparatus command unit 17.

In step S30, the acquisition apparatus/interval determination unit. 16 acquires (receives) a combination of apparatus numbers uniquely specifying the measurement apparatuses 3 and physical quantities, which are measurement values, from the acquisition apparatus command unit 17. The acquisition apparatus/interval determination process starts upon the receipt. When the measurement apparatus 3 is installed on the power line 61, a physical quantity which is a measurement, value is the physical quantity of the power line 61, and when the measurement apparatus 3 is attached to the power source, a physical quantity is the physical quantity of the power source.

In step S31, the acquisition apparatus/interval determination unit 16 reads a value recorded in the apparatus number column 153a of the acquisition apparatus/interval determination rule 153, and determines whether the value is the same as the acquired apparatus number. When conditions for the determination are established (Yes), the acquisition apparatus/interval determination unit 16 performs step S32, and when the conditions for the determination are not established (No), the acquisition apparatus/interval determination unit 16 returns to step S30. When the determination conditions in step S31 are established, the acquisition apparatus/interval determination unit 16 is capable of acquiring a physical quantity measured by the first measurement apparatus among the measurement apparatuses 3.

In step S32, the acquisition apparatus/interval determination unit 16 reads the acquisition apparatus/interval determination rule 153, and based on the acquisition apparatus/interval determination rule 153, determines the second measurement apparatus from which a measurement value is acquired, the acquisition interval, and the acquisition start sequence from the physical quantities acquired in step S30. Specifically, the acquisition apparatus/interval determination unit 16 looks up the apparatus number column 153a and the threshold value column 153b of the acquisition apparatus/interval determination rule 153 for the apparatus numbers and the measurement values acquired in step S30. The acquisition apparatus/interval determination unit 16 acquires a record in which the acquired apparatus numbers match information in the apparatus number column 153a, and the acquired measurement values satisfy the conditions in the threshold value column 153b. The acquisition apparatus/interval determination unit 16 determines a combination of records in the acquisition apparatus number column 153c, the acquisition interval column 153d, and the acquisition start sequence column 153e as the second measurement apparatus, the acquisition interval, and the acquisition start sequence.

That is, the acquisition apparatus/interval determination unit 16 is capable of selecting the second measurement apparatus, and determining the time interval for acquiring a measurement value, and the acquisition start sequence, based on a physical quantity measured by the first measurement apparatus.

For example, when a combination (of an apparatus number and a measurement value) acquired in step S30 is (#4, 6500), the acquisition apparatus/interval determination unit 16 acquires the records in the second to ninth rows in FIG. 4, and determines the second measurement apparatuses.

Combinations of the determined second measurement apparatuses (an apparatus number, an acquisition interval, and an acquisition start sequence) are (#0, 60, 1), (#1, 0, -), (#2, 60, 2), (#3, 60, 3), (#4, 60, 4), (#5, 0, -), (#6, 0, -), and (#7, 60, 5).

When a combination (of an apparatus number and a measurement value) acquired in step S30 is (#4, 6750), the acquisition apparatus/interval determination unit 16 acquires the records in the tenth to seventeenth rows in FIG. 4, and determines the second measurement apparatuses. Combinations of the determined second measurement apparatuses (an apparatus number, an acquisition interval, and an acquisition start sequence) are (#0, 50, 5), (#1, 0, -), (#2, 0, -), (#3, 0, -), (#4, 30, 1), (#5, 30, 2), (#6, 30, 3), and (#7, 30, 4).

In step S33, the acquisition apparatus/interval determination unit 16 writes and registers the apparatus number for an apparatus from which a measurement value is acquired, the acquisition interval, and the acquisition start, sequence, which are determined in step S32, in the acquisition apparatus/interval determination history 155. A date and time determined in step S32, and the physical quantity and the threshold value used for this determination are written and registered in the acquisition apparatus/interval determination history 155 by the acquisition apparatus/interval, determination unit 16. Accordingly, an operator of the power system 6 can understands a malfunction or the like by understanding an operation state of the power system monitoring and control apparatus 1 later.

When a combination (of an apparatus number and a physical quantity) acquired in step S32 is (#4, 6500), the acquisition apparatus/interval determination unit 16 registers the records in the second to ninth rows in FIG. 6. When a combination (of an apparatus number and a physical quantity) acquired in step S32 is (#4, 6750), the acquisition apparatus/interval determination unit 16 registers the records in the eleventh to eighteenth rows in FIG. 6.

In step S34, the acquisition apparatus/interval determination unit 16 transmits a combination of the apparatus number for an apparatus from which a measurement value is acquired, the acquisition interval, and the acquisition start sequence, which are determined in step S32, to the acquisition apparatus command unit 17. Accordingly, the acquisition apparatus/interval determination unit 16 is capable of issuing a command to the second measurement apparatus via the acquisition apparatus command unit 17. When step S34 ends, the acquisition apparatus/interval determination unit 16 returns to step S30.

FIG. 10 is a chart illustrating the coincidence of acquisition timings in the first embodiment.

A rightward direction represents a common time. An initial line represents the measurement apparatus 3-4 with apparatus number #4. On-line circles represent the timings of the acquisition of measurement values. The measurement apparatus 3-4 acquires measurement values at time intervals of 30 seconds.

A second line represents the measurement apparatus 3-5 with apparatus number #5. On-line circles represent the timings of the acquisition of measurement values. The measurement apparatus 3-5 acquires measurement values at time intervals of 30 seconds. The measurement apparatuses 3-4 and 3-5 acquire the measurement values at different timings.

A third line represents the measurement apparatus 3-0 with apparatus number #0. On-line circles represent the timings of the acquisition of measurement values. The measurement apparatus 3-0 acquires measurement values at time intervals of 50 seconds, and acquisition timings coincide with each other at time Tj. At this time, the acquisition apparatus command unit 17 determines the sequence of acquiring the measurement values from both apparatuses based on the respective acquisition start sequences of the measurement apparatuses 3-0 and 3-5. For example, when the measurement apparatus 3-0 is set to have a high acquisition start sequence, the acquisition apparatus command unit 17 is capable of acquiring measurement values from the measurement apparatus 3-0 at accurate timings.

### Second Embodiment

The acquisition apparatus/interval determination unit 16 in the first embodiment directly acquires a physical quantity, which is measured by the first measurement apparatus, from the acquisition apparatus command unit 17. In contrast, the acquisition apparatus/interval determination unit 16 in a second embodiment acquires a physical quantity that is estimated and interpolated from measurement values acquired by the measurement apparatuses 3 at other points.

In the first embodiment, for example, each of the records in the second to ninth rows of the apparatus number column 153a in FIG. 4 is “#4” indicating the apparatus number of the first measurement apparatus 3-4. In contrast, in the second embodiment, each of the records in the apparatus number column 153a is “#1” indicating the measurement apparatus 3-1 from which a measurement value is not acquired. A physical quantity for the measurement apparatus 3-1 is estimated and interpolated from other measurement values. Hereinafter, the configuration and the operation of the second embodiment will be specifically described.

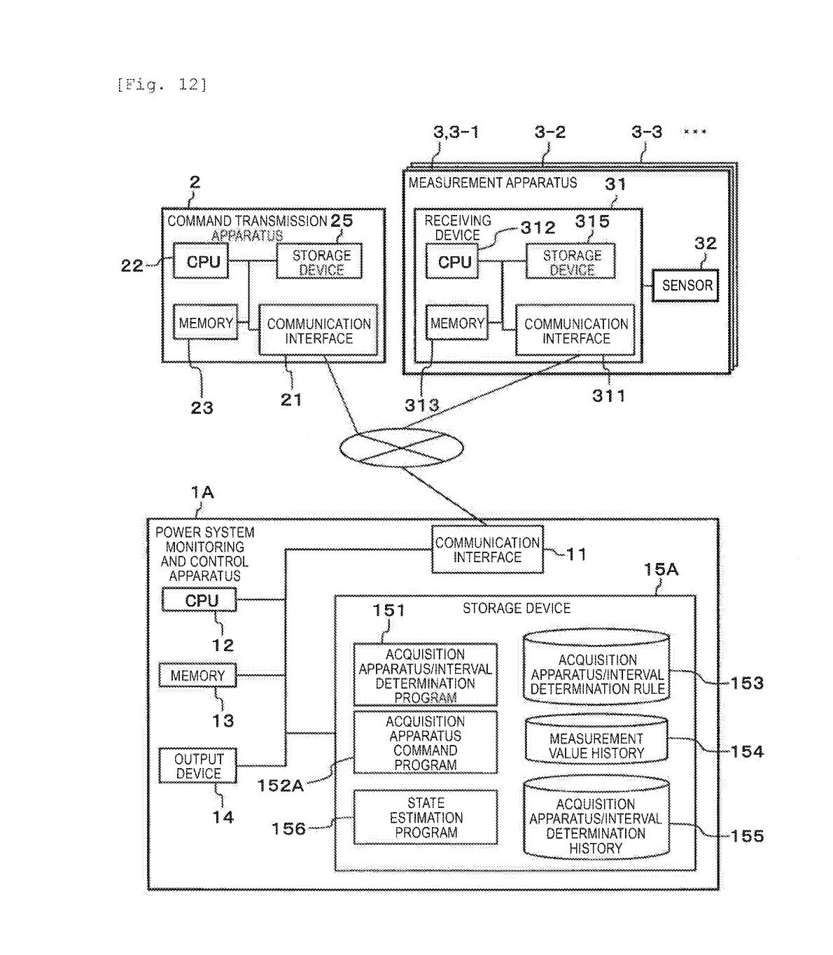

FIG. 11 is a block diagram illustrating the logic configuration of a power system monitoring and control apparatus 1A in the second embodiment. The same reference signs are assigned to the same configuration elements as those of the power system monitoring and control apparatus 1 in the first embodiment illustrated in FIG. 1.

As illustrated in FIG. 11, the power system monitoring and control apparatus 1A in the second embodiment, includes an acquisition apparatus command unit 17A different from the acquisition apparatus command unit 17 in the first embodiment, and further includes a state estimation unit 18. Except for these configuration elements, the power system, monitoring and control apparatus 1A is configured similar to the power system monitoring and control apparatus 1 {refer to FIG. 1} in the first embodiment.

The acquisition apparatus command unit 17A in the second embodiment transmits a physical quantity and an apparatus number, which are acquired via the command transmission apparatus 2, to the state estimation unit 18, and stores the physical quantity and the apparatus number in the measurement, value history 154.

The state estimation unit 18 estimates and interpolates a measurement value of the first measurement apparatus from, measurement values acquired by the measurement apparatuses 3 at other points. Similarly, the state estimation unit 18 indirectly estimates and interpolates a physical quantity at each point in the vicinity of the first measurement apparatus from measurement values of the second measurement apparatuses, which are acquired via the acquisition apparatus command unit 17A. The state estimation unit 18 transmits the estimated physical quantity at each point to the acquisition apparatus/interval determination unit 16, and stores the estimated physical quantities in the measurement value history 154. Accordingly, it is possible to reduce the number of measurement apparatuses 3 which acquire measurement values, or to extend a time interval during which each of the measurement apparatuses 3 acquires a measurement value, and thus the power system monitoring and control apparatus 1A is capable of monitoring the power system 6 even if a communication path 9 has a low communication speed.

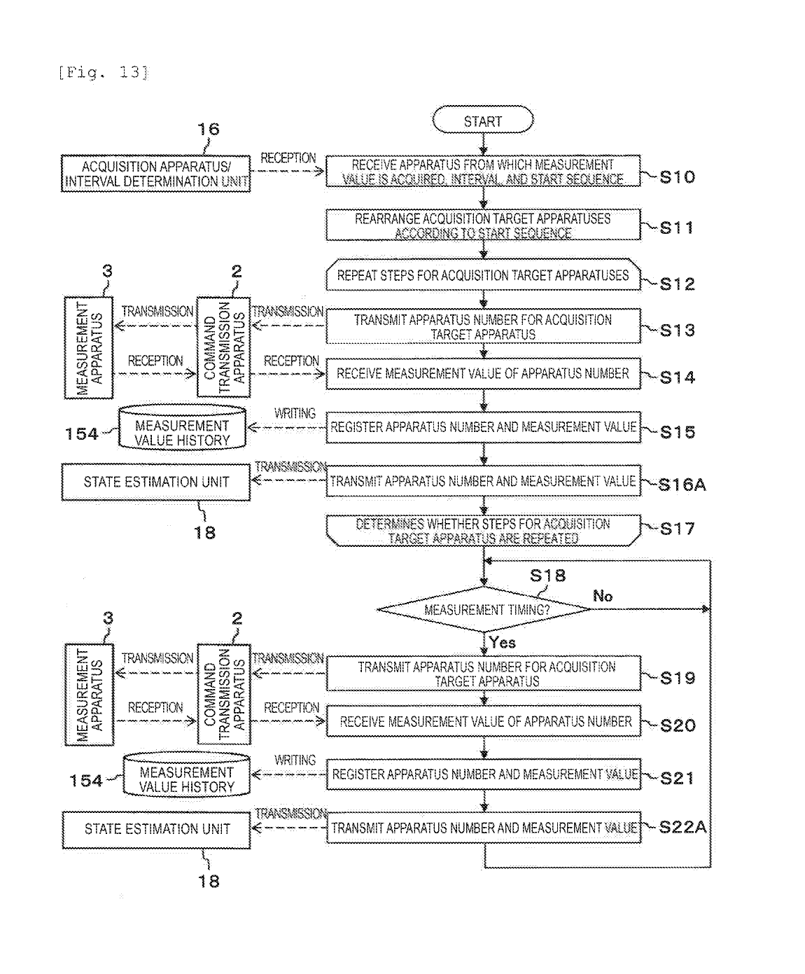

FIG. 12 is a block diagram illustrating the physical configuration of the power system, monitoring and control apparatus 1A in the second embodiment. The same reference signs are assigned to the same configuration elements as in the power system monitoring and control apparatus 1 in the first embodiment, illustrated in FIG. 2.

As illustrated in FIG. 12, the power system monitoring and control apparatus 1A in the second embodiment includes a storage device 15A different from the storage device 15 in the first embodiment.

The storage device 15A in the second embodiment stores an acquisition apparatus command program 152A that is different from the acquisition apparatus command program 152 stored in the storage device 15 in the first embodiment. The storage device 15A further stores a state estimation program 156. Except for these programs, the storage device 15A stores the same programs or data as those stored in the storage device 15 (refer to FIG. 2) in the first embodiment.

The acquisition apparatus command program 152A is reads onto the memory 13 and is executed by the CPU 12 such that the acquisition apparatus command unit 17A (refer to FIG. 11) is realized.

Similarly, the state estimation program 156 is read onto the memory 13 and is executed by the CPU 12 such that the state estimation unit 18 (refer to FIG. 11) is realized.

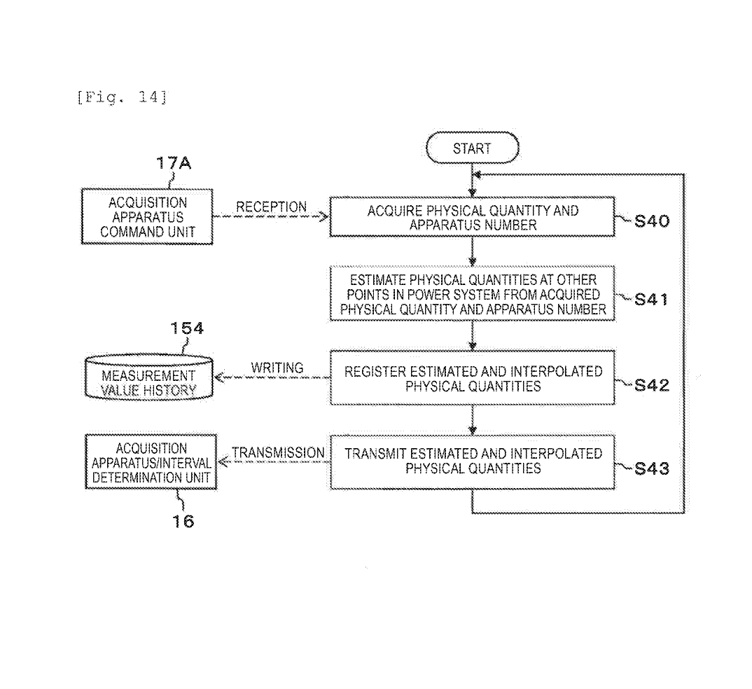

FIG. 13 is a flowchart illustrating an acquisition apparatus command process in the second embodiment. The same reference signs are assigned to the same elements as in the flowchart in the first embodiment illustrated in FIG. 7.

Similar to the first embodiment, the acquisition apparatus command program 152 is executed by the CPU 12 such that the acquisition apparatus command unit 17A in the second embodiment is realized, and starts the process. Steps S10 to S11 are the same as steps S10 to S11 illustrated in FIG. 7.

The acquisition apparatus command unit 17A repeats steps S12 to S15, S16A, and S17 for acquisition target apparatuses. The acquisition apparatus command unit 17A acquires an initial measurement value from each of the acquisition target apparatuses according to an acquisition start sequence by performing these steps.

Steps S13 to S15 are the same as steps S13 to S15 illustrated in FIG. 7.

In step S16A, the acquisition apparatus command unit 17A transmits a combination of an apparatus number and a measurement value to the state estimation unit 18.

In step S17, the acquisition apparatus command unit 17A determines whether the steps for the acquisition target apparatus are repeated. When conditions for the determination are not established, the acquisition apparatus command unit 17A returns to step S12.

In step S18, based on a previous measurement value acquisition, timing and the acquisition interval of each of the acquisition target apparatuses, the acquisition apparatus command unit 17A determines whether a current time is a measurement timing of any one of the acquisition target apparatuses. When the determination conditions are not established, the acquisition apparatus command unit 17A repeats step S18, and when the determination conditions are established, the acquisition apparatus command unit 17A performs step S19. In step S18, when acquisition timings of a plurality of the acquisition target apparatuses coincide with each other, the acquisition apparatus command unit 17A performs steps for the acquisition target apparatus with an early acquisition start sequence prior to other acquisition target apparatuses. Steps S19 to S21, and S22A to be illustrated hereinafter are the same as steps S13 to S15, and S16A.

Steps S19 to S21 are the same as steps S19 to S21 illustrated in FIG. 7.

In step S22A, the acquisition apparatus command unit 17A transmits an apparatus number and a measurement value to the state estimation unit 18, and returns to step S18.

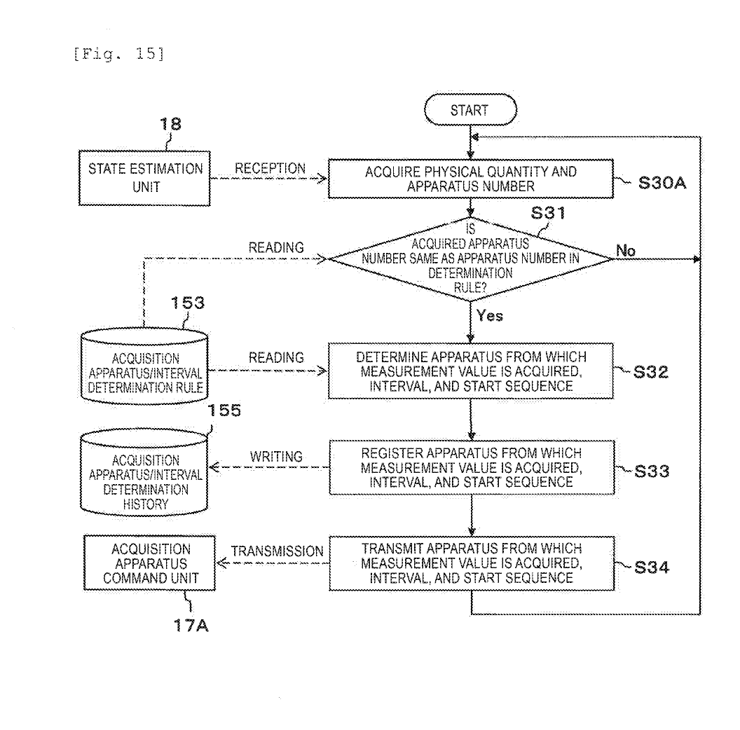

FIG. 14 is a flowchart illustrating a state estimation process in the second embodiment.

The state estimation program 156 is executed by the CPU 12 such that the state estimation unit 18 is realized, and starts the process.

In step S40, the state estimation unit 18 acquires (receives) a combination of apparatus numbers uniquely specifying the measurement apparatuses 3 and physical quantities, which are measurement values, from the acquisition apparatus command unit 17A. The state estimation process starts upon the receipt.

In step S41, the state estimation unit 18 estimates physical quantities at other points in the power system 6 from the acquired physical quantities and apparatus numbers. For example, the method disclosed in NPL 2 may be used as an estimation method.

In step S42, the state estimation unit 18 writes and registers the estimated and interpolated physical quantities in the measurement value history 154.

In step S43, the state estimation unit 18 transmits the estimated and interpolated physical quantities to the acquisition apparatus/interval determination unit 16, and returns to step S40.

Accordingly, the power system monitoring and control apparatus 1A is capable of understanding physical quantities at many points in the power system 6 without increasing the amount of communication between the measurement apparatuses 3 and the power system monitoring and control apparatus 1A.

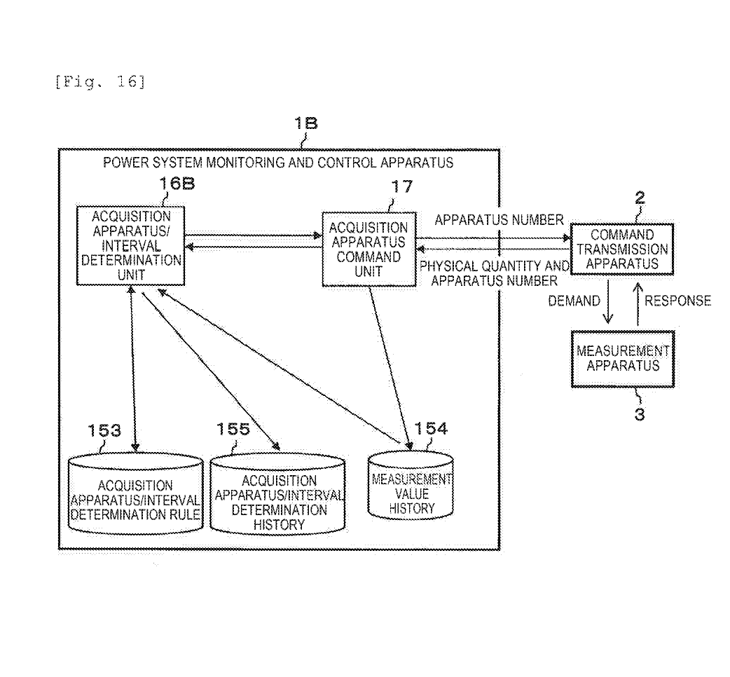

FIG. 15 is a flowchart illustrating an acquisition apparatus/interval determination process in the second embodiment. The same reference signs are assigned to the same elements as in the acquisition apparatus/interval determination process in the first embodiment illustrated in FIG. 9.

After the start of the process, in step S30A, the acquisition apparatus/interval determination unit 16 acquires (receives) a combination of apparatus numbers uniquely specifying the measurement apparatuses 3 and physical quantities, which are measurement values, from the state estimation unit 18. The acquisition apparatus/interval determination process starts upon the receipt. When the measurement apparatus 3 is installed on the power line 61, a physical quantity which is a measurement value is the physical quantity of the power line 61, and when the measurement apparatus 3 is attached to the power source, a physical quantity is the physical quantity of the power source.

Steps S31 to S34 are the same as steps S31 to S34 (refer to FIG. 9) in the first embodiment.

In step S34, the acquisition apparatus/interval determination unit. 16 transmits a combination of the apparatus number for an apparatus from which a measurement value is acquired, the acquisition interval, and the acquisition start sequence to the acquisition apparatus command unit 17A. Accordingly, the acquisition apparatus/interval determination unit 16 is capable of issuing a command to the second measurement apparatus via the acquisition apparatus command unit 17A. When step S34 ends, the acquisition apparatus/interval determination unit 16 returns to step S30.

As such, in the acquisition apparatus/interval determination process according to the second embodiment, the state estimation unit 18 acquires and processes physical quantities which are indirectly estimated from measurement values of the second measurement apparatuses. Accordingly, it is possible to reduce the number of second measurement apparatuses which acquire measurement values, or to extend a time interval during which each of the second measurement apparatuses acquires a measurement value.

### Third Embodiment

In the first embodiment, an operator of the power system is required to set optimal values in the acquisition apparatus/interval determination rule 153 in advance. Accumulation data, that is, a physical quantity measured at each point in the power system over a predetermined period of time, is required to calculate the optimal values set in the acquisition apparatus/interval determination rule 153. Accordingly, operational man hours for the power system monitoring and control, apparatus increases, and a time lag until the start of an operation occurs, which is a problem. In contrast, in the third embodiment, a power system monitoring and control apparatus dynamically optimizes the acquisition apparatus/interval determination rule 153 by, for example, learning a threshold value indicating a normal range and an abnormal range of a physical quantity. Accordingly, the third embodiment does not require man hours to calculate the optimal values set in the acquisition apparatus/interval determination rule 153, and it is possible to quickly start the operation of the power system monitoring and control apparatus. Hereinafter, the configuration and the operation, of the third embodiment will be specifically described.

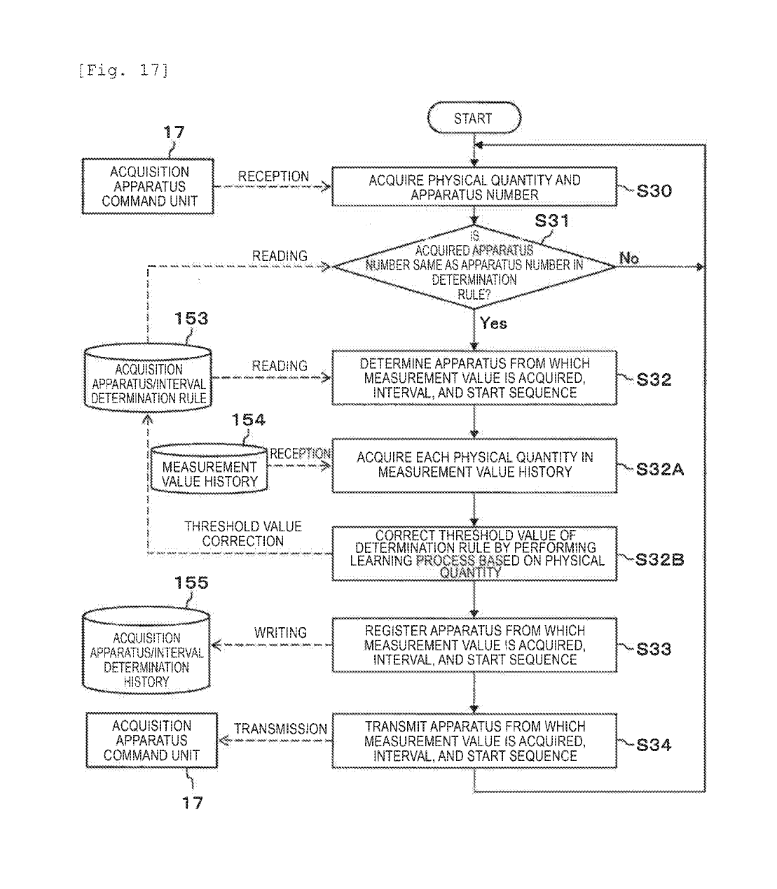

FIG. 16 is a block diagram illustrating the logic configuration of a power system monitoring and control apparatus 1B in the third embodiment. The same reference signs are assigned to the same configuration elements as in the power system monitoring and control apparatus 1 in the first embodiment illustrated in FIG. 1.

As illustrated in FIG. 16, the power system monitoring and control apparatus 1B in the third embodiment includes an acquisition apparatus/interval determination unit 16B different from the acquisition apparatus/interval determination unit 16 in the first embodiment. Except for the acquisition apparatus/interval determination unit, the power system monitoring and control apparatus 1B has the same configuration as the power system monitoring and control apparatus 1 in the first embodiment.

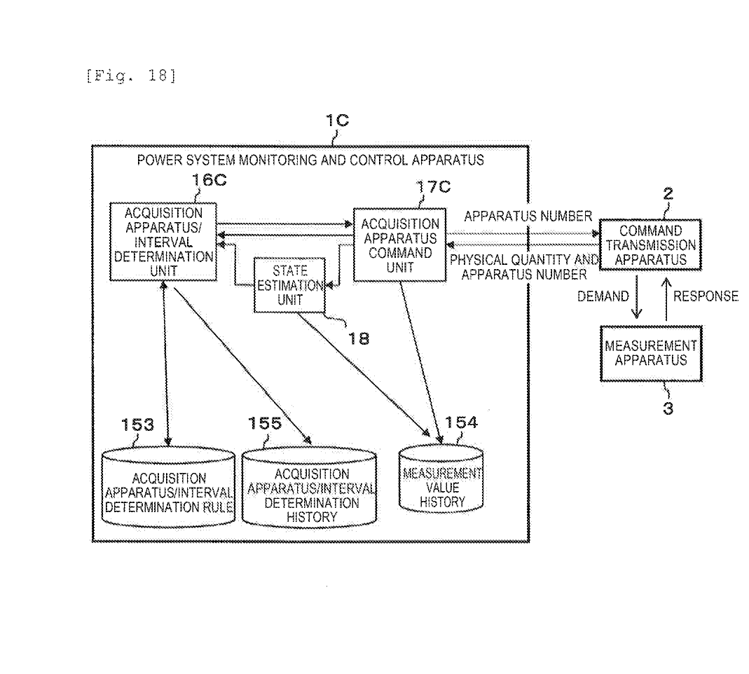

In addition to the same function as the acquisition apparatus/interval determination unit 16 in the first embodiment, the acquisition apparatus/interval determination unit 16B in the third embodiment has a function of correcting the threshold value of the acquisition apparatus/interval determination rule 153 by learning a normal range, an abnormal range, or the like of a physical quantity based on the acquired physical quantity. An acquisition apparatus/interval determination process executed by the acquisition apparatus/interval determination unit 16B will be described in detail with reference to FIG. 17.

FIG. 17 is a flowchart illustrating the acquisition apparatus/interval determination process in the third embodiment. The same reference signs are assigned to the same elements in the acquisition apparatus/interval determination process in the first embodiment illustrated in FIG. 9.

After the start of the process, steps S30 to S32 are the same as steps S30 to S32 (refer to FIG. 9) in the first embodiment. When step S32 ends, the acquisition apparatus/interval determination unit 16B performs step S32A.

In step S32A, the acquisition apparatus/interval determination unit 16B acquires (receives) physical quantities from the measurement value history 154. Accordingly, the acquisition apparatus/interval determination unit 16B is capable of making reference to the physical quantities at each point up to now, and, for example, improving the accuracy of a learning process (to be described later). When step S32A ends, the acquisition apparatus/interval determination unit 16B performs step S32B.

In step S32B, the acquisition apparatus/interval determination unit 16B corrects the threshold value of the acquisition apparatus/interval determination rule 153 by, based, on the acquired physical quantity, learning a normal range, an abnormal range, or the like of the physical quantity of the power line, with the physical quantity being measured by the first measurement apparatus. Accordingly, the acquisition apparatus/interval determination unit 16B is capable of optimizing the acquisition apparatus/interval determination rule 153, and more appropriately determining whether a physical quantity measured by the first measurement apparatus is normal. When step S32B ends, the acquisition apparatus/interval determination unit 16B performs step S33.

Steps S33 and S34 are the same as steps S33 and S34 (refer to FIG. 9) in the first embodiment. When step S34 ends, the acquisition apparatus/interval determination unit 16B returns step S30.

### Modification Example of Third Embodiment

The power system, monitoring and control apparatus 1B in the third embodiment dynamically optimizes the acquisition apparatus/interval determination rule 153 by performing the learning process based on the physical quantities acquired from the measurement value history 154. In contrast, a power system monitoring and control apparatus in a modification example of the third embodiment dynamically optimizes the acquisition apparatus/interval determination rule 153 by performing the learning process based on the physical quantities interpolated and estimated by the state estimation unit 18. Hereinafter, the configuration and the operation of the modification example of the third embodiment will be specifically described.

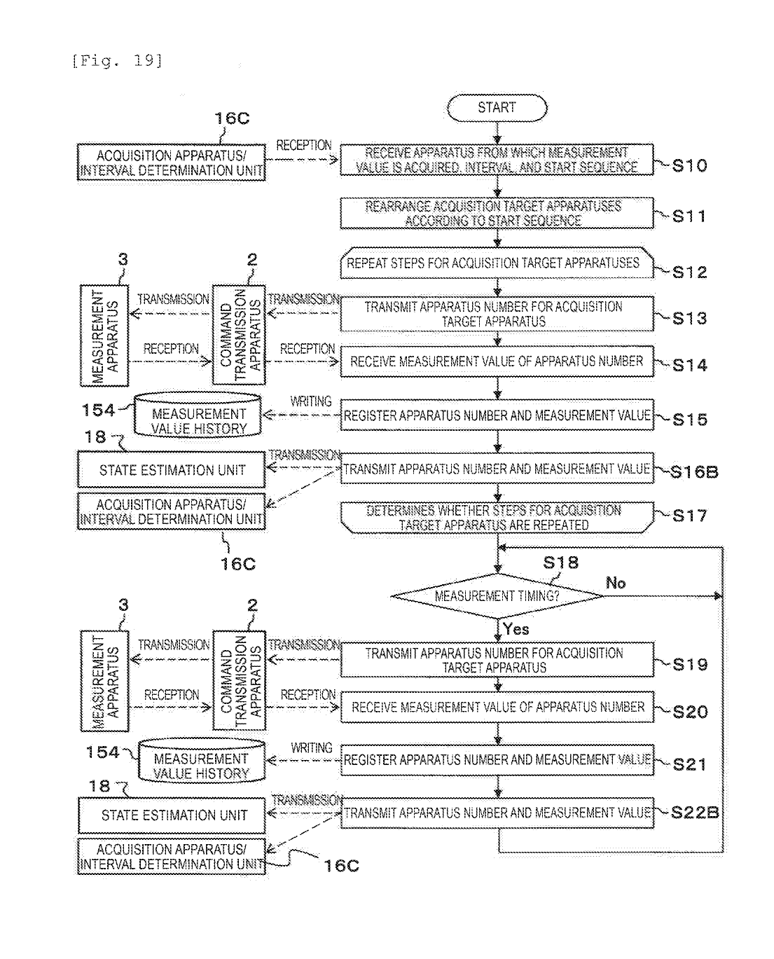

FIG. 18 is a block diagram illustrating the logic configuration of a power system, monitoring and control apparatus 1C in the modification example of the third embodiment. The same reference signs are assigned to the same configuration element as in the power system, monitoring and control apparatus 1A in the second embodiment illustrated in FIG. 11, or in the power system monitoring and control apparatus 1B in the third embodiment illustrated in FIG. 16.

As illustrated in FIG. 18, the power system monitoring and control apparatus 1C in the modification example of the third embodiment includes an acquisition apparatus/interval determination unit 16C that is the same as the acquisition apparatus/interval determination unit 16B in the third embodiment; an acquisition apparatus command unit 17C different from the acquisition apparatus command unit 17 in the third embodiment; and the same state estimation unit 18 as in the second embodiment.

The acquisition apparatus/interval determination unit 16C in the modification example of the third embodiment has a function of correcting the threshold value of the acquisition apparatus/interval determination rule 153 by learning a normal range, an abnormal range, or the like of a physical quantity based on the acquired physical quantity. An acquisition apparatus/interval determination process executed, by the acquisition apparatus/interval determination unit 16C will be described in detail with reference to FIG. 20.

The acquisition apparatus command unit 17C in the modification example of the third embodiment has the same function as the acquisition apparatus command unit 17A in the second embodiment, transmits physical quantities and apparatus numbers, which are acquired via the command transmission apparatus 2, to the state estimation unit 18 and the acquisition apparatus/interval determination unit 16C, and stores the physical quantities and the apparatus numbers in the measurement value history 154. The acquisition apparatus command unit 17C transmits the acquired physical quantities and apparatus numbers to the acquisition apparatus/interval determination unit 16C via the state estimation unit 18, and thus it is possible to reduce the number of measurement apparatuses 3 which acquire measurement values, and to extend a time interval during which each of the measurement apparatuses 3 acquires a measurement value. The acquisition apparatus command unit 17C directly transmits the acquired physical quantities and apparatus numbers to the acquisition apparatus/interval determination unit 16C. Accordingly, the acquisition apparatus/interval determination unit 16C quickly is capable of receiving a physical quantity at each point in the power system 6, and determining the measurement apparatuses 3 from which measurement values are acquired, the acquisition interval, and the like without delay.

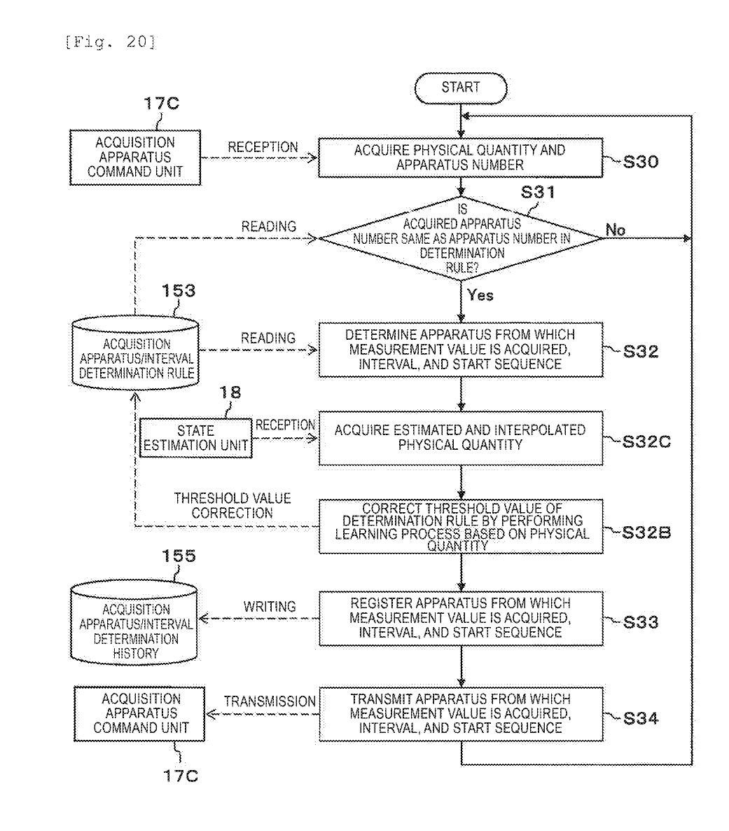

An acquisition apparatus command process executed by the acquisition apparatus command unit 17C will be described in detail with reference to FIG. 19.

The state estimation unit 18 in the modification example of the third embodiment has the same function as the state estimation unit 18 in the second embodiment, and performs the state estimation process illustrated in FIG. 14.

FIG. 19 is a flowchart illustrating the acquisition apparatus command process in the modification example of the third embodiment. The same reference signs are assigned to the same elements as in the flowchart in the second embodiment illustrated in FIG. 13.

Similar to the second embodiment, the acquisition apparatus command program 152 is executed by the CPU 12 such that the acquisition apparatus command unit 17C in the modification example of the third embodiment is realized, and starts the process.

Steps S10 and S11 are the same as step S10 and S11 illustrated in FIG. 13.

The acquisition apparatus command unit 17C repeats steps S12 to S15, S16B, and S17 for acquisition target apparatuses. The acquisition apparatus command unit 17C acquires an initial measurement value from each of the acquisition target apparatuses according to an acquisition start sequence by performing these steps.

Steps S13 to S15 are the same as steps S13 to S15 illustrated in FIG. 13.

In step S16B, the acquisition apparatus command unit 17C transmits a combination of an apparatus number and a measurement value to the state estimation unit 18 and the acquisition apparatus/interval determination unit. 16C.

In step S17, the acquisition apparatus command unit 17C determines whether the steps for the acquisition target apparatus are repeated. When conditions for the determination are not established, the acquisition apparatus command unit 17C returns to step S12.

In step S18, based on a previous measurement value acquisition timing and the acquisition interval of each of the acquisition target apparatuses, the acquisition apparatus command unit 17C determines whether a current time is a measurement timing of any one of the acquisition target apparatuses. When the determination conditions are not established, the acquisition apparatus command unit 17C repeats step S18, and when the determination conditions are established, the acquisition apparatus command unit 17C performs step S19. In step S18, when acquisition timings of a plurality of the acquisition target apparatuses coincide with each other, the acquisition apparatus command unit 17C performs steps for the acquisition target apparatus with an early acquisition start sequence prior to other acquisition target apparatuses. Steps S19 to S21, and S22B to be illustrated hereinafter are the same as steps S13 to S15, and S16B.

Steps S19 to S21 are the same as steps S19 to S21 illustrated in FIG. 13.

In step S22B, the acquisition apparatus command unit 17C transmits an apparatus number and a measurement value to the state estimation unit 18 and the acquisition apparatus/interval determination unit 16C, and returns to step S18.

FIG. 20 is a flowchart illustrating an acquisition apparatus/interval determination process in the modification example of the third embodiment. The same reference signs are assigned to the same elements in the acquisition apparatus/interval determination process in the third embodiment illustrated in FIG. 17.

After the start of the process, steps S30 to S32 are the same as steps S30 to S32 (refer to FIG. 17) in the third embodiment. When step S32 ends, the acquisition apparatus/interval determination unit 16C performs step S32C.

In step S32C, the acquisition apparatus/interval determination unit 16C acquires (receives) physical quantities at other points from the state estimation unit 18, with the physical quantities being estimated and interpolated by the state estimation unit 18. Accordingly, the acquisition apparatus/interval determination unit 16C is capable of acquiring physical quantities at more points, and improving the accuracy of the learning process. When step S32C ends, the acquisition apparatus/interval determination unit 16C performs step S32B.

In step S32B, the acquisition apparatus/interval determination unit 16C corrects the threshold value of the acquisition apparatus/interval determination rule 153 by, based on the acquired, physical quantity, learning a normal range, an abnormal range, or the like of the physical quantity of the power line, with the physical quantity being measured by the first measurement, apparatus. Accordingly, the acquisition apparatus/interval determination unit 16C is capable of optimizing the acquisition apparatus/interval determination rule 153, and more appropriately determining whether a physical quantity measured by the first measurement apparatus is normal. When step S32B ends, the acquisition apparatus/interval determination unit 16C performs step S33.

Steps S33 and S34 are the same as steps S33 and S34 (refer to FIG. 17) in the third embodiment.

In step S34, the acquisition apparatus/interval determination unit 16C transmits a combination of the apparatus number for an apparatus from which a measurement value is acquired, the acquisition interval, and the acquisition start sequence to the acquisition apparatus command unit 17C. Accordingly, the acquisition apparatus/interval determination unit 16C is capable of issuing a command to the second measurement apparatus via the acquisition apparatus command unit 17C. When step S34 ends, the acquisition apparatus/interval determination unit 16C returns to step S30.

### MODIFICATION EXAMPLES

The present invention is not limited to the aforementioned embodiments, and includes various modification examples. The embodiments have been described in detail so that the present invention can be easily understood, and the present invention is not limited to a configuration in which all of the aforementioned configuration elements are necessarily included. Portions of the configuration of an embodiment can be replaced with the configuration of another embodiment, and the configuration of another embodiment can be added to the configuration of an embodiment. The addition, the removal, and the replacement of another configuration can be made to portions of the configuration of each of the embodiments.

Portions or the entirety of the aforementioned configurations, functions, processing units, processing means, and the like may be realized by hardware such as an integrated circuit. A processor analyzes and executes a program realizing each of the functions such that each of the aforementioned configurations, functions, and the like may be realized by software. Pieces of information such as programs, tables, and files realizing functions can be placed in a recording device such as a memory, a hard disk, and a solid state drive (SSD), or in a recording medium such as a flash memory card or a digital versatile disk (DVD).

Each of the embodiments illustrates only control lines or information lines which are deemed to be required for descriptive purposes, and does not illustrate all of control lines or information lines which are required to complete a product. Actually, almost ail of the configuration elements may be deemed to be connected to each other.

The modification examples of the present invention are described in (a) to (h) hereinbelow.

(a) In the first embodiment, as illustrated in FIGS. 1 and 2, the power system monitoring and control apparatus 1 and the command transmission apparatus 2 are separately provided. However, the present invention is not limited to that configuration, and the command transmission apparatus 2 may be integrally configured such that the command transmission apparatus 2 has the function of the power system monitoring and control apparatus 1.

(b) In the first embodiment, as illustrated in FIGS. 1 and 2, the power system monitoring and control apparatus 1 and the measurement, apparatus 3 are separately provided. However, the present invention is not limited to that configuration, and the measurement apparatus 3 may be integrally configured such that the measurement apparatus 3 has the function of the power system monitoring and control, apparatus 1.

(c) In the first embodiment, as illustrated in FIGS. 1 and 2, the command transmission apparatus 2 and the measurement apparatus 3 are separately provided. However, the present invention is not limited to that configuration, and the measurement apparatus 3 may be integrally configured such that the measurement apparatus 3 has the function of the command transmission apparatus 2.

(d) In the first embodiment, the acquisition apparatus/interval determination unit 16 determines the second measurement apparatus from which a measurement value is acquired, the acquisition interval, and the acquisition start sequence based on the physical quantity of a power line. However, the present invention is not limited to that configuration, and the acquisition apparatus/interval determination unit 16 may determine the second measurement apparatus from, which a measurement value is acquired, the acquisition interval, and the acquisition start sequence based on the physical quantity of a power source.

For example, the power system monitoring and control apparatus 1 determines whether the amount of power generation of the photovoltaic apparatus 5 is large in a certain time period, based on a power generation value (measurement value) or an expected value (estimated value) of the photovoltaic apparatus 5. In this time period, the power system monitoring and control apparatus 1 selects most of the neighboring measurement apparatuses 3 connected to the photovoltaic apparatus 5 as the second measurement apparatuses, and decreases an acquisition interval. In addition, the power system, monitoring and control apparatus 1 does not select the neighboring measurement apparatuses 3, which are not connected to the photovoltaic apparatus 5, as the second measurement apparatuses, or increases a measurement value acquisition interval.

(e) In the first embodiment, the power system 6 includes the photovoltaic apparatus 5 as a distributed power source. However, the present invention is not limited to that configuration, and as a distributed power source, the power system 6 may include a wind power generator, a solar power generator, a hydroelectric power generator, a tidal power generator, a wave power generator, an ocean current power generator, a biomass power generator, a geothermal power generator, a temperature difference power generator, and the like.

(f) In the first embodiment, the acquisition apparatus/interval determination unit 16 determines the second measurement apparatus from which a measurement value is acquired, the acquisition interval, and the acquisition start sequence according to a static rule such as the acquisition apparatus/interval (determination rule 153. However, the present invention is not limited to that configuration, and the acquisition apparatus/interval determination unit 16 may dynamically determine the second measurement apparatus from which a measurement value is acquired, the acquisition interval, and the acquisition start sequence from measurement values which are required, by state estimation means or system control means. For example, the method disclosed in NPL 2 may be the state estimation means. For example, the method disclosed in NPL 3 may be the system control means.

(g) The acquisition apparatus/interval determination unit 16 may optimize values of each of the items such as the threshold value column 153b, the acquisition interval column 153d, and the like of the acquisition apparatus/interval determination rule 153 by evaluating monitoring accuracy and performing a learning process while the acquisition apparatus/interval determination process, the acquisition apparatus command process, or the like is repeated.

(h) In the first, embodiment, a measurement value which can be acquired by the measurement apparatus 3 is a type of physical quantity. However, the prevent invention is not limited to a type of physical quantity, and a measurement value which can be acquired by the measurement apparatus 3 may be a plurality of types of physical quantities. Accordingly, the power system monitoring and control apparatus 1 is capable of more accurately understanding the state of the power system 6. The plurality of types of physical quantities may be acquired at once, and may be sequentially acquired one by one. Accordingly, the power system monitoring and control apparatus 1 is capable of selectively acquiring necessary measurement values.

### REFERENCE SIGNS LIST

1, 1A, 1B, 1C: POWER SYSTEM MONITORING AND CONTROL APPARATUS
11: COMMUNICATION INTERFACE
12: CPU
13: MEMORY
14: OUTPUT DEVICE
15, 15A: STORAGE DEVICE
151: ACQUISITION APPARATUS/INTERVAL DETERMINATION PROGRAM
152, 152A: ACQUISITION APPARATUS COMMAND PROGRAM
153: ACQUISITION APPARATUS/INTERVAL DETERMINATION RULE
154: MEASUREMENT VALUE HISTORY
155: ACQUISITION APPARATUS/INTERVAL DETERMINATION HISTORY
156: STATE ESTIMATION PROGRAM
16, 16B, 16C: ACQUISITION APPARATUS/INTERVAL DETERMINATION UNIT (DETERMINATION UNIT)
17, 17A, 17C: ACQUISITION APPARATUS COMMAND UNIT (COMMAND UNIT)
18: STATE ESTIMATION UNIT
2: COMMAND TRANSMISSION APPARATUS
21: COMMUNICATION INTERFACE
22: CPU
23: MEMORY
25: STORAGE DEVICE
3, 3-0 TO 3-7: MEASUREMENT DEVICE
3-4: FIRST MEASUREMENT APPARATUS
3-0 TO 3-7: SECOND MEASUREMENT APPARATUS
31: RECEIVING DEVICE
311: COMMUNICATION INTERFACE
312: CPU
313: MEMORY
315: STORAGE DEVICE
32: SENSOR
4: POWER DISTRIBUTION AND TRANSFORMATION STATION
5, 5-1, 5-2: PHOTOVOLTAIC APPARATUS
6: POWER SYSTEM
61: POWER LINE
9: COMMUNICATION PATH

1. A power system monitoring and control apparatus comprising:
a command unit configured to command a plurality of measurement apparatuses to acquire a physical quantity of a power line or a power source; and
a determination unit configured to select second measurement apparatuses based on the physical quantity acquired by a first measurement apparatus, and to determine a time interval, during which the second measurement apparatuses acquire measurement values, so as to acquire a physical quantity at each point in the vicinity of the first measurement apparatus among the plurality of measurement apparatuses.

2. The power system monitoring and control apparatus according to claim 1,
wherein the physical quantity acquired by the measurement apparatus contains any one of a voltage, current, an effective power, and a non-effective power.

3. The power system monitoring and control apparatus according to claim 1,
wherein the command unit directly acquires the physical quantity at each point in the vicinity of the first measurement apparatus by means of the second measurement apparatuses.

4. The power system monitoring and control apparatus according to claim 1, further comprising:
a state estimation unit configured to indirectly estimate the physical quantity at each point in the vicinity of the first measurement apparatus from the measurement values acquired by the second measurement apparatuses.

5. The power system monitoring and control apparatus according to claim 1, further comprising:
a storage device configured to store information,
wherein the command unit commands the storage device to store a history of the measurement values acquired by the second measurement apparatuses.

6. The power system monitoring and control apparatus according to claim 5,
wherein the determination unit registers a history of a determination of selecting the second measurement apparatuses and determining a time interval, during which the second measurement apparatuses acquire measurement values, in the storage device.

7. The power system monitoring and control apparatus according to claim 6,
wherein the storage device stores a determination rule that determines the second measurement apparatuses based on the physical quantity acquired by the first measurement apparatus, and the time interval during which the second measurement apparatuses acquire measurement values.

8. The power system monitoring and control apparatus according to claim 7,
wherein a learning process is performed in such a way that the determination rule is optimized based on the history of the measurement values acquired by the second measurement apparatuses.

9. The power system monitoring and control apparatus according to claim 7, further comprising:
a state estimation unit configured to indirectly estimate the physical quantity of the power line or the power source from the measurement values acquired by the measurement apparatuses,
wherein a learning process is performed in such a way that the determination rule is optimized based on the physical quantity that the state estimation unit indirectly estimates from the measurement values acquired by the measurement apparatuses.

10. The power system monitoring and control apparatus according to claim 7,
wherein the determination rule further contains information regarding a start sequence according to which the second measurement apparatuses acquire measurement values.

11. The power system monitoring and control apparatus according to claim 10,
wherein the history of the determination contains information regarding the start sequence according to which the second measurement apparatuses acquire measurement values.

12. A power system monitoring and control method that is executed, by a power system monitoring and control apparatus including a command unit configured to command a measurement apparatus to acquire a physical quantity of a power line or a power source, and a determination unit configured to determine a time interval during which a measurement value is acquired,
wherein the determination unit executes
a step of acquiring a physical quantity by means of a first measurement apparatus among a plurality of the measurement apparatuses,
a step of selecting second measurement apparatuses based on the physical quantity measured by the first measurement apparatus, and determining a time interval of the acquisition of a measurement value,
a step of issuing a command to the second measurement apparatus via the command unit, and
a step of acquiring a physical quantity at each point in the vicinity of the first measurement apparatus.
